(19) United States
(12) Patent Application Publication
(10) Pub. No.: US 2015/0262693 A1
(43) Pub. Date: Sep. 17, 2015

(54) NONVOLATILE SEMICONDUCTOR MEMORY DEVICE

(71) Applicant: KABUSHIKI KAISHA TOSHIBA, Minato-ku (JP)

(72) Inventor: Shigeo KONDO, Yokkaichi-shi (JP)

(73) Assignee: KABUSHIKI KAISHA TOSHIBA, Minato-ku (JP)

(21) Appl. No.: 14/641,700

(22) Filed: Mar. 9, 2015

Related U.S. Application Data
(60) Provisional application No. 61/952,434, filed on Mar. 13, 2014.

(51) Int. Cl. G11C 16/28; G11C 16/10; G11C 16/04

(52) U.S. Cl. CPC G11C 16/28; G11C 16/0483; G11C 16/10

(57) ABSTRACT

A nonvolatile semiconductor memory device according to embodiment comprises: a memory cell array configured to include word lines and memory strings, the memory strings having memory cells connected in series, the memory cells being connected to the word lines; and a control unit configured to execute a read sequence to read data page-by-page, the control unit, during the read sequence on a first page, executing a read operation by applying a first read-pass voltage to a second word line and reading data in the first page, and executing a re-read operation by applying a second read-pass voltage different from the first read-pass voltage to the second word line and reading data in a first cell in a case where data read from a first cell group in the first page coincides with a specific first reference pattern.

### CROSS-REFERENCE TO RELATED APPLICATIONS

This application is based upon and claims the benefit of priority from the prior U.S. Provisional Application 61/952,434, filed on Mar. 13, 2014, the entire contents of which are incorporated herein by reference.

### BACKGROUND

1. Field

Embodiments of the present invention relate to a nonvolatile semiconductor memory device.

2. Description of the Related Art

A NAND flash memory is known as a nonvolatile semiconductor memory device that can be electrically rewritten with high data density. In the NAND flash memory, a few tens of memory cells form a NAND string by connecting adjacent memory cells in series sharing a source/drain diffusion layer. Both ends of the NAND string are connected to a bit line and a source line via a selection gate transistor, respectively. Such a configuration enables smaller unit cell area and a larger memory capacity as compared with a NOR flash memory.

A memory cell of the NAND flash memory has a floating gate (charge storage layer) formed on a semiconductor substrate via a tunnel insulation film and a control gate stacked on the floating gate (charge storage layer) via an inter-gate insulation film. Data are stored in a nonvolatile way corresponding to the electric charge of the floating gate. For example, a positively-charged floating gate (lacking electrons) has a low threshold voltage. Such a state is regarded as “1” data, and thus binary data are stored. So-called “multi-level cell” such as a four-level cell (2 bits/cell) and an eight-level cell (3 bits/cell) is also possible by further fractionating written (or “programmed”) threshold voltage distribution (Writing operations of the flash memory is often referred to as “programming” for historical reasons).

However, recent scaling of the NAND flash memory cell brings greater cell-to-cell interference and channel-to-floating-gate interference. These unfavorable effects make it difficult to precisely control threshold voltage distributions and read them without errors.

### BRIEF DESCRIPTION OF THE DRAWINGS

FIG. 1 illustrates a block diagram showing a nonvolatile semiconductor memory device according to a first embodiment;

FIG. 2 illustrates a circuit diagram of a memory cell array in a nonvolatile semiconductor memory device according to the first embodiment;

FIG. 3 illustrates how a threshold voltage distribution of memory cells evolves during a program sequence of the nonvolatile semiconductor memory device;

FIG. 4 illustrates an example of memory cell states in a read sequence in the nonvolatile semiconductor memory device according to the first embodiment;

FIG. 5 illustrates an example of memory cell states in a read sequence in the nonvolatile semiconductor memory device according to the first embodiment;

FIG. 6 illustrates an example of a histogram showing a threshold voltage distribution of memory cells in the read sequence in the nonvolatile semiconductor memory device according to the first embodiment;

FIG. 7 illustrates another example of memory cell states in a read sequence in the nonvolatile semiconductor memory device according to the first embodiment;

FIG. 8 illustrates another example of memory cell states in a read sequence in the nonvolatile semiconductor memory device according to the first embodiment;

FIG. 9 illustrates an example of memory cell states in a program sequence (verify-read sequence) in a nonvolatile semiconductor memory device according to a comparative example for a second embodiment;

FIG. 10 illustrates an example of memory cell states in a read sequence in the nonvolatile semiconductor memory device according to the comparative example;

FIG. 11 illustrates an example of memory cell states in a read sequence in the nonvolatile semiconductor memory device according to the comparative example;

FIG. 12 illustrates an example of memory cell states in a read sequence in the nonvolatile semiconductor memory device according to the comparative example;

FIG. 13 illustrates an example of memory cell states in a read sequence in the nonvolatile semiconductor memory device according to the second embodiment;

FIG. 14 illustrates an example of memory cell states in a read sequence in the nonvolatile semiconductor memory device according to the second embodiment;

FIG. 15 illustrates a histogram of threshold voltage distributions of the memory cells in the read sequence in the nonvolatile semiconductor memory device according to the second embodiment;

FIG. 16 illustrates a relation of a margin of the threshold voltage distribution to a difference in the read-pass voltages between read and re-read operations in the nonvolatile semiconductor memory device according to the second embodiment;

FIG. 17 illustrates schematically a mechanism of channel-to-floating-gate interference during a program sequence in the nonvolatile semiconductor memory device;

FIG. 18 illustrates a mechanism of channel-to-floating-gate interference during a program sequence in the nonvolatile semiconductor memory device;

FIG. 19 illustrates a relation of a threshold voltage of a memory cell to a program voltage during a program sequence in the nonvolatile semiconductor memory device;

FIG. 20 illustrates time evolution of program pulses and verify-read pulses during a program sequence in the nonvolatile semiconductor memory device according to a third embodiment;

FIG. 21 illustrates an example of channel-voltage states of memory cells during a program sequence in the nonvolatile semiconductor memory device according to the third embodiment;

FIG. 22 illustrates a flow chart of a program sequence in the nonvolatile semiconductor memory device according to the third embodiment;

FIG. 23 illustrates a histogram showing the threshold voltage distribution of memory cells after a program sequence in the nonvolatile semiconductor memory device according to the third embodiment;

FIG. 24 illustrates an example of channel-voltage states during a program sequence in the nonvolatile semiconductor memory device according to a fourth embodiment;

FIG. 25 illustrates a flow chart of a program sequence in the nonvolatile semiconductor memory device according to the fourth embodiment;

FIG. 26 illustrates a histogram showing the threshold voltage distribution of memory cells after a program sequence in the nonvolatile semiconductor memory device according to the fourth embodiment;

FIG. 27 illustrates time evolution of program pulses and verify-read pulses during a program sequence in the nonvolatile semiconductor memory device according to a fifth embodiment;

FIG. 28 illustrates a flow chart of a program sequence in the nonvolatile semiconductor memory device according to the fifth embodiment;

FIG. 29 illustrates a histogram showing the threshold voltage distribution of memory cells after a program sequence in the nonvolatile semiconductor memory device according to the fifth embodiment; and

FIG. 30 illustrates time evolution of program pulses and verify pulses during a program sequence in the nonvolatile semiconductor memory device according to a sixth embodiment.

### DETAILED DESCRIPTION

A nonvolatile semiconductor memory device according to embodiment comprises: a memory cell array configured to include more than one word lines and more than one memory strings, the memory strings having more than one memory cells connected in series, the memory cells being connected to the word lines; and a control unit configured to execute a read sequence to read data page-by-page including more than one memory cells connected to one word line, the control unit, during the read sequence on a first page, executing a read operation by applying a first read-pass voltage to a second word line and reading data in the first page, and executing a re-read operation by applying a second read-pass voltage different from the first read-pass voltage to the second word line and reading data in a first cell in a case where data read from a first cell group in the first page coincides with a specific first reference pattern, where a first word line refers to one of the word lines that the control unit tries to read, the second word line refers to one of the word lines adjacent to the first word line, the page refers to data stored in memory cells connected to a whole word line, the first page refers to the page stored in the first word line, the cell group refers to one or more memory cells continuously placed and connected to the same word line, and the first cell refers to a memory cell belonging to the cell group and under judgment for being re-read.

Hereafter, nonvolatile semiconductor memory devices according to embodiments will be described with reference to the drawings.

### First Embodiment

First, a general configuration of a nonvolatile semiconductor memory device according to a first embodiment will now be described. Note that in the ensuing description, a NAND flash memory is taken as an example.

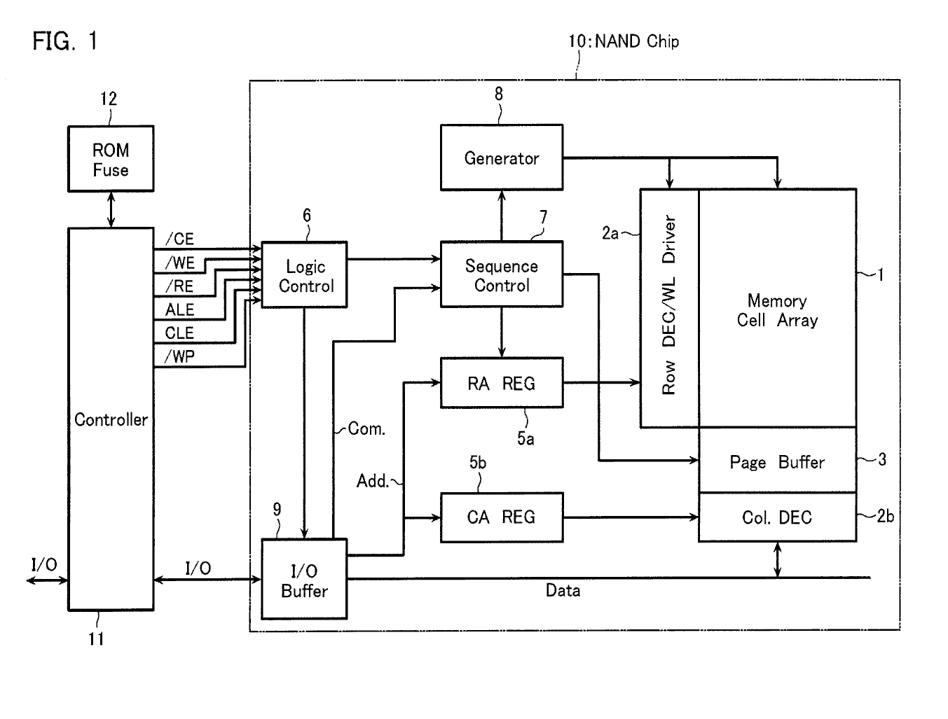

FIG. 1 is a block diagram of a nonvolatile semiconductor memory device according to the present embodiment.

The flash memory includes a NAND chip 10, a controller 11 configured to control the NAND chip 10, and a ROM fuse 12 configured to store various kinds of information required to access the NAND chip 10.

The NAND chip 10 includes a memory cell array 1. The memory cell array 1 includes more than one bit lines extending in a column direction, more than one word lines and source lines extending in a row direction. Memory cells are formed at all the intersection points between bit lines and word lines. The memory cell array 1 will be described in detail later.

Note that data reading and programming in the present embodiment are conducted page-by-page. Here, a “page” is a set of data that the control unit can read or program at the same time from or to the memory cell array 1, which is equivalent to one-word-line data, because the read or program operations are performed word line by word line. In a case where one memory cell stores multiple bits, a single word line can store multiple pages. In the present embodiment, however, as for the latter case, for example, in a case where two bits/cell are used, a page consisting of upper bits of each memory cell is referred to as an “upper page” and a page consisting of lower bits of each memory cell is referred to as a “lower page” for discrimination.

The NAND chip 10 includes a control unit configured to execute sequential operations of reading and programming. The control unit includes a row decoder/word line driver 2a, a column decoder 2b, a page buffer 3, a row address register 5a, a column address register 5b, a logic control circuit 6, a sequence control circuit 7, a voltage generation circuit 8, and an I/O buffer 9.

The row decoder/word line driver 2a drives a word line and a selected gate line which will be described later in the memory cell array 1. The page buffer 3 includes sense amplifier circuits and data holding circuits corresponding to one page. Read out data corresponding to one page retained by the page buffer 3 are column-selected subsequently by the column decoder 2b, and output to an external I/O terminal via the I/O buffer 9. Program data supplied from the I/O terminal is selected by the column decoder 2b, and loaded into the page buffer 3. Program data corresponding to one page is loaded into the page buffer 3. A row address signal and a column address signal are input via the I/O buffer 9, and are transferred to the row decoder 2a and the column decoder 2b, respectively. The row address register 5a retains an erased block address in a case of data erasing, and retains a page address in a case of data reading and programming. A head column address for loading program data before starting a program sequence, or a head column address for a read sequence is input to the column address register 5b. The column address register 5b retains the input column address until a write enable /WE or a read enable /RE is toggled under a predetermined condition.

The logic control circuit 6 controls command and address inputting and data inputting and outputting on the basis of controls signals such as a chip enable signal /CE, a command enable signal CLE, an address latch enable signal ALE, a write enable signal /WE, and a read enable signal /RE. A read operation and a program operation are conducted on the basis of a command. Upon receiving a command, the sequence control circuit 7 executes sequence control of a read, program or erase operation. A voltage generation circuit 8 is controlled by the sequence control circuit 7 to generate predetermined voltages required for various operations.

The controller 11 controls a read sequence and a program sequence under a condition suitable for a current program state of the NAND chip 10. Note that as for a part of the read sequence and the program sequence, it is also possible for the control unit in the NAND chip 10 to control.

The memory cell array 1 in the nonvolatile semiconductor memory device according to the present embodiment will now be described.

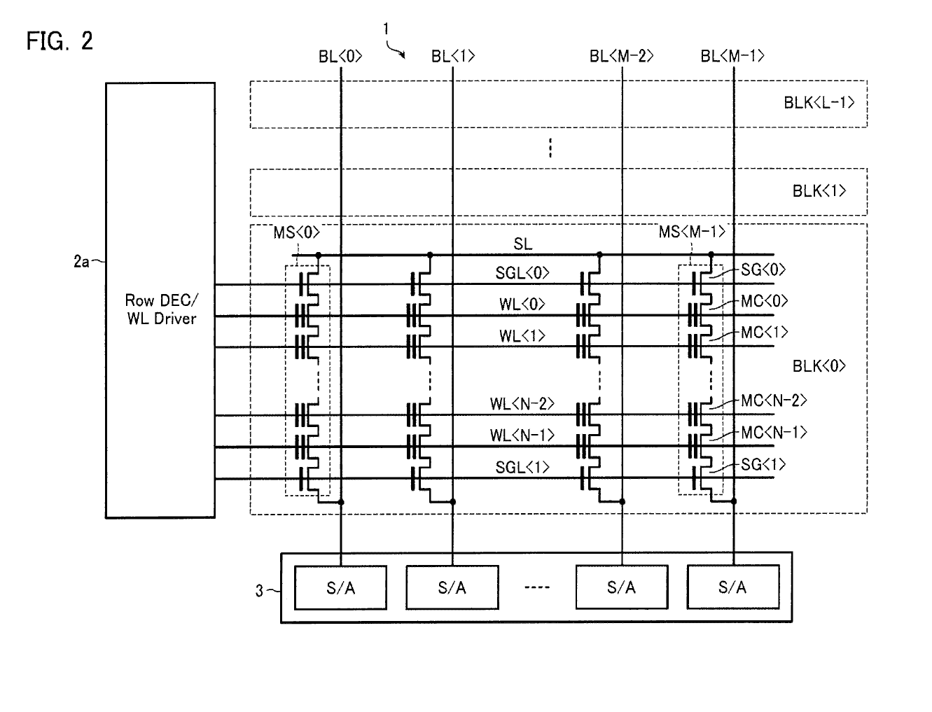

FIG. 2 is a circuit diagram of the memory cell array in the nonvolatile semiconductor memory device according to the present embodiment.

The memory cell array 1 includes N word lines WL<0> to <N−1>, selection gate lines SGL<0> and <1>, and a source line SL extending in the row direction, M bit lines BL<0> to <M−1> extending in the column direction, and M memory strings MS<0> to <M−1>. Each memory string MS includes N memory cells MC<0> to <N−1> connected in series and selection gate transistors SG<0> and <1> connected to both ends of them. Each memory cell MC is formed as a transistor consisting of a channel on a semiconductor substrate, a floating gate (charge storage layer) formed on a channel, and a control gate formed on the floating gate.

A source region of the selection gate transistor SG<0> is connected to the source line SL. A drain region of the selection gate transistor SG<1> is connected to one of the bit lines BL<0> to <M−1>. Control gates of the memory cells MC<0> to <N−1> are connected to the word lines WL<0> to <N−1>. Gates of the selection gate transistors SG<0> and <1> are connected to the selection gate line SGL<0> and <1>, respectively.

In the above-described configuration, M memory strings MS arranged in the row direction constitute one block BLK. The block BLK is a minimal unit of data erasing. The memory cell array 1 includes L blocks BLK<0> to <L−1> arranged in the column direction. The word line WL and the selection gate line SGL are driven by the row decoder 2a. Each bit line BL is connected to a sense amplifier circuit S/A in the page buffer 3.

A program sequence according to the present embodiment is described below.

Note that in the following description, a memory cell MC of 2 bits/cell is used as an example. However, all the embodiments are applicable to memory cells of 3, 4, or other bits/cell. The threshold voltage distributions of the memory cells MC are labeled as an ER level, an A level, a B level, and a C level in the level growing order, and 2-bit data of “11,” “01,” “00” or “10” are respectively assigned to each threshold voltage distribution as an example.

In the ensuing description, the following terms are used: A predetermined page that the control unit tries to read is referred to as “selected page” and other pages are referred to as “unselected pages.” Among the unselected pages, at least one of pages adjacent to the selected page is referred to as “adjacent page.” A predetermined memory cell that the control unit tries to access is referred to as “selected cell” and other memory cells are referred to as “unselected cells.” Among the unselected cells, at least one of memory cells belonging to the same page as the selected cell and adjacent to the selected cell is referred to as “adjacent cell.” A word line connected to the selected cell is referred to as “selected word line” and other word lines are referred to as “unselected word lines.” Among the unselected word lines, at least one word line adjacent to the selected word line is referred to as “adjacent word line.” A memory string to which the selected cell belongs is referred to as “selected string” and other memory strings are “unselected strings.” Among the unselected strings, at least one memory string adjacent to the selected string is referred to as “adjacent string.” A bit line connected to the selected string is referred to as “selected bit line” and other bit lines are referred to as “unselected bit lines.” Among the unselected bit lines, at least one bit line adjacent to the selected bit line is referred to as “adjacent bit line.”

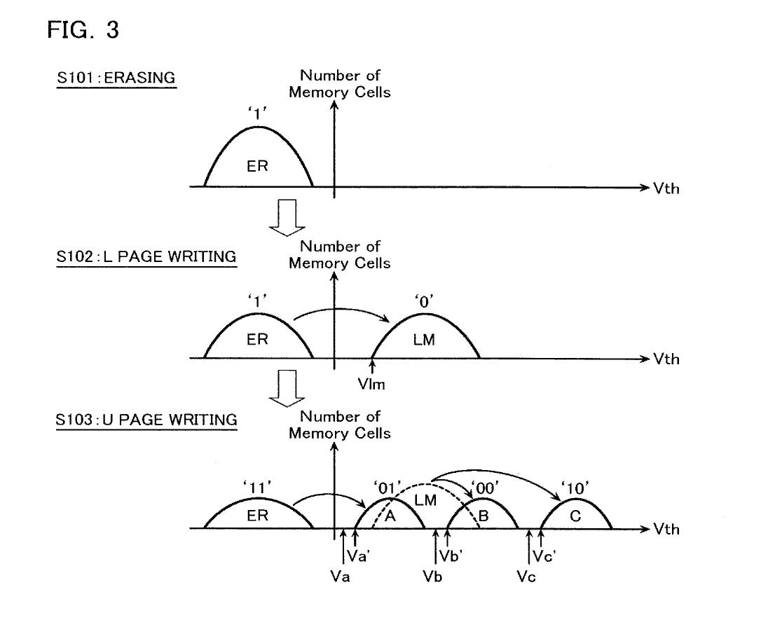

FIG. 3 illustrates how the threshold voltage distribution of the memory cells changes during a program sequence in the nonvolatile semiconductor memory device according to the present embodiment.

First, an erasing step is executed at step S101. At this step, data in all memory cells MC in the block BLK are erased in the lump. As a result, threshold voltages Vth's of all memory cells MC in the block BLK shift to the lowest ER level.

Subsequently, at step S102, an L page program step is executed. In a case of 2 bits/cell, two page data are allocated on one word line. At the L page program step, low-order bits (or the first page) of allocated two-page data are programmed onto the selected word line as L page data. Each bit of the L page data is regarded as a low-order bit of each cell. If the low-order bit of the memory cell MC is “1,” the threshold voltage Vth of the memory cell MC is kept at the ER level. If the low-order bit of a memory cell MC is “0,” the threshold voltage Vth of the memory cell MC is shifted from the ER level to an LM level, which is an intermediate level between the A level and the B level.

Finally, at step S103, a U page program step is executed. At the U page program step, the second page of allocated two-page data is programmed as U page of the selected word line. Each bit of the U page data is regarded as an upper-order bit of each cell. If the threshold voltage Vth of the memory cell MC is the ER level while an upper bit to be programmed on the memory cell MC is “1,” the threshold voltage Vth of the memory cell MC is kept at the ER level. If the upper bit to be programmed on the memory cell MC is “0,” the threshold voltage Vth of the memory cell MC is shifted to the A level. On the other hand, in a case where the threshold voltage Vth of the memory cell MC is the LM level and an upper bit to be programmed on the memory cell MC is “0,” the threshold voltage Vth of the memory cell MC is shifted to the B level. In a case where the upper bit of the program data is “1,” the threshold voltage Vth of the memory cell MC is shifted to the C level.

Thus, the L page program step and the U page program step are executed to program 2-bit data into the memory cell MC. Typically a few tens of program loops are repeated for each program step. Each program loop mainly consists of a program operation and a verify-read operation. The program operation shifts the threshold voltage Vth of the memory cell MC, and a verify-read operation verifies whether the threshold voltage Vth of the memory cell MC has reached to a desired value.

During the program operation, the selection gate transistor SG<0> on the source line SL side is held to a non-conductive state, while the selection gate transistor SG<1> on the bit line BL side of the selected block is held to a conductive state or non-conductive state depending on whether the memory string MS is selected or unselected. If the threshold voltage Vth of a memory cell MC is to be shifted, the corresponding memory string MS connected to the memory cell MC is set to the selected state, that is, the selection gate SG<1> on the bit line BL side is held to the conductive state by applying a ground voltage Vss (0V) to the bit line (selected bit line) BL. As a result, the channel voltage of the selected string MS becomes Vch=Vss. If in this biased state the program voltage Vpgm (e.g., approximately ˜20 V) is applied to the selected word line WL and a program-pass voltage Vpps is applied to the unselected word lines WL, an intense electric field is generated between a floating gate and a channel of the selected cell MC, and electrons are injected into the floating gate of the selected cell MC by a tunnel current. As a result, the threshold voltage Vth of the selected cell MC shifts in the positive direction.

On the other hand, in a case where the threshold voltage Vth of a memory cell MC is not to be shifted, the corresponding memory string MS is set to an unselected (or inhibited) state, where the selection gate SG<1> on the bit line BL side is brought into the non-conductive state by applying the power supply voltage Vcc (e.g. typically 3.3 V) to the bit line BL. As a result, the channel of the selected string MS is subjected to preliminary charging. If in addition the program voltage Vpgm is applied to the selected word line WL and the program-pass voltage Vpps is applied to the unselected word lines WL, the channel voltage Vch of the selected string MS is boosted up to the inhibit voltage Vinh (e.g., approximately ˜5 V, where “˜” indicates a floating state) by the capacitive coupling between the control gate and the channel in the memory cell MC. As a result, injection of electrons into the floating gate of the unselected cell MC is prevented.

Before describing the read sequence according to the present embodiment, a comparative example of a traditional read sequence is described in the following part.

The read sequence includes a read operation.

When detecting the threshold voltage Vth (data) of the selected cell MC, the reference voltage Vcgr=Va, Vb, or Vc is applied to the selected word line WL, and the read-pass voltage Vrps (e.g., typically 6 V) is applied to the unselected word lines WL. The reference voltage Va, Vb, or Vc are set between the threshold voltage distributions, and the read-pass voltage Vrps is set to a higher value than the upper tail of the threshold voltage distribution of the highest level (the C level for 2 bit/cell memories). If the cell current does not flow through memory string MS under the applied reference voltage Vcgr=Vc, the threshold voltage Vth of the selected cell MC is found to be the C level. Conversely, if the cell current flows through the memory string MS, the threshold voltage Vth of the selected cell MC is found to be lower than the C level.

Note that the verify-read operation in the program sequence is the same as the read operation except that the verify-read voltage indicating a lower limit of threshold voltage distribution Vvrf=Va′, Vb′ and Vc′ is used instead of the reference voltage Vcgr.

In the above-described program sequence, however, the following problem occurs. The program sequence of the selected word line WL is always performed from lower voltages to higher voltages. Therefore, programming of lower level cells finishes earlier than higher level cells. In the case of 2 bit/cell memories, threshold voltages Vth of the A-level cells typically reach their verify-read voltage first, the B-level cells reach their verify-read voltage next, and finally the C-level cells reach their verify-read voltage. In other words, the C-level cells require more program loops than the A-level cells until they reach the threshold voltage of their own level. Note that the ER-level cells are not assumed to be programmed here. If some of the A-level cells MC are adjacent to the C-level cells on the selected word line, for example, the threshold voltages of the program-finished A-level cells gradually shift upward because of the continuing programming on the adjacent C-level cells and the inter-bit-line cell-to-cell interference. In the worst case, programming into the memory cells MC causes an error.

In the present embodiment, therefore, a read sequence is invented so that influence of such inter-bit-line cell-to-cell interference on the memory cell MC is cancelled posteriorly as described below.

In a case where data stored in more than one consecutive memory cells MC are found to coincide with a specific pattern (first reference pattern) by the above-described read operation according to the present embodiment, a re-read operation is executed on all of the memory cells MC or a part of them on the same word line. The re-read operation is performed with another read-pass voltage on the adjacent word line different from the read-pass voltage Vrps applied at the first read operation. Hereafter, a concrete example in the present embodiment will be described.

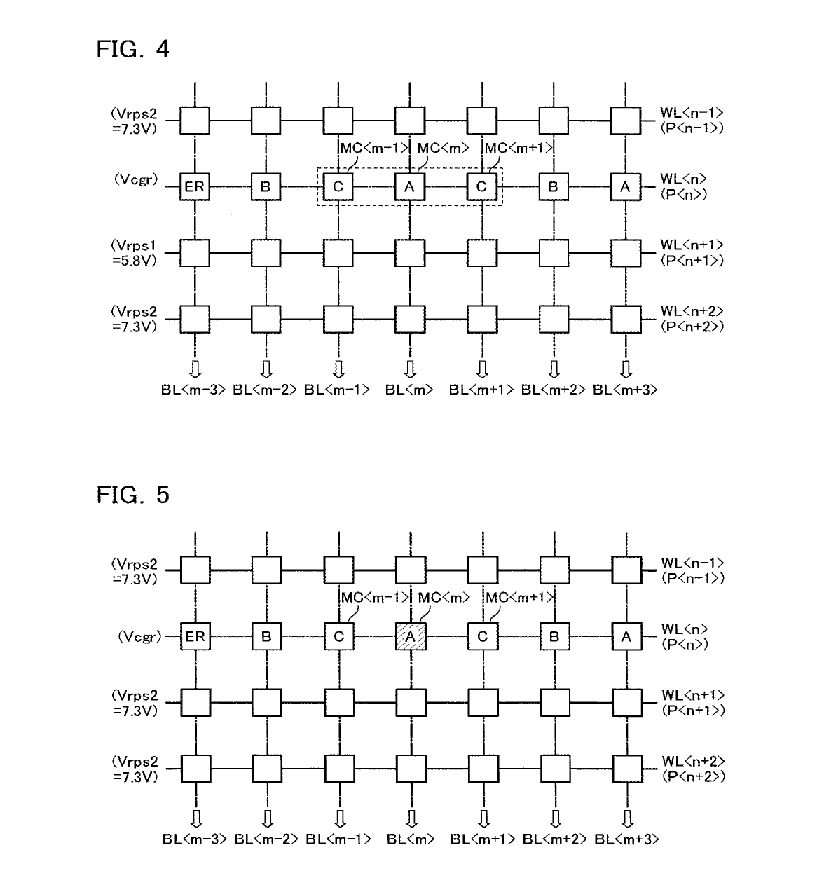

FIGS. 4 and 5 illustrate an example of the read sequence in the nonvolatile semiconductor memory device according to the present embodiment.

First, in FIG. 4, a read operation on the selected page P<n> is executed. Here, the reference voltage Vcgr is applied to the selected word line WL<n>, a read-pass voltage Vrps1=5.8 V is applied to the adjacent word line WL<n+1>, and a read-pass voltage Vrps2=7.3 V is applied to other unselected word lines WL. A level of the threshold voltage Vth in each memory cell MC in the selected page P<n> found by this read operation (hereafter referred to as “Vth level”) is shown in FIG. 4.

Subsequently, in FIG. 5, a re-read operation on the selected page P<n> is executed. A set of continuously placed three cells extracted arbitrarily from the selected word line is referred to as “cell group” here. The target of the re-read operation of the present example is the center cell MC of the cell group having a data pattern of C level-ER level/A level-C level. All the coincident cell groups on the selected word line are targeted to be re-read. In the case of FIG. 5, the threshold voltage Vth of continuously placed three memory cells MC<m−1> to <m+1> in the page P<n> surrounded by a dashed line in FIG. 4 coincides with the C level-A level-C level. Therefore, a re-read operation is executed on the cell MC<m>, which is the center of the cell group and in the A level as shaded in FIG. 5. In this re-read operation, a read-pass voltage Vrps2=7.3 V is applied to the adjacent word line WL<n+1>, which is higher than that of the first read operation. Except the read-pass voltage of the adjacent word line, the re-read operation is the same as the first read operation shown in FIG. 4. The final threshold voltage Vth of the selected cell MC<m> is determined by this re-read operation. According to this re-read operation, the threshold voltage Vth of the selected cell MC<m> can be read seemingly lower than the actual threshold voltage Vth by raising the read-pass voltage of the adjacent word line WL<n+1>.

Note that the read-pass voltage applied to the adjacent word line WL<n+1> at the first read operation (Vrps1=5.8 V in FIG. 4) does not have to be lower than the read-pass voltage of other unselected word lines (Vrps2=7.3 V in FIG. 4). However, if the read-pass voltage at the first read operation (Vrps1=5.8 V in the case of FIG. 4) is held down to a low value, a too high read-pass voltage can be avoided at the re-read operation (Vrps2=7.3 V in the case of FIG. 5), which suppresses unintentional charge injection into the adjacent cell MC<m+1>. In addition, it is possible to reduce the number of generated voltages and prevent the peripheral circuit from becoming complicated by sharing the read-pass voltage among all unselected word lines WL including the adjacent word line WL<n+1> during there-read operation.

Effects of the read sequence in the present embodiment is as follows: Influence of the inter-bit-line cell-to-cell interference on the selected cell MC<m> is maximized when the threshold voltages Vth's in the cell group coincides with the pattern of the C level-ER level-C level. This is because the selected cell of the ER level is not programmed after the erase step whereas programming of the adjacent C-level cells MC<m−1> and <m+1> continues up to the U page program step, and in addition, the magnitude of the threshold voltage Vth shift of the adjacent cells MC<m−1> and <m+1> at the L page program step and the U page program step is greater than the case in which the adjacent cells are in other levels. Therefore, the threshold voltage Vth of the ER-level selected cell shifts to the A level more possibly when the adjacent cells are in the C level than other cases.

The present embodiment reduces the above-described unfavorable influence of the cell-to-cell interference. The threshold voltage of the selected cell MC<m> can be read seemingly low if the data pattern of the cell group coincides with the C level-Er or A level-C level. Even if the selected cell MC<m> is originally set to the ER level and read out as the A level at the first read operation, the read-out result can be corrected as the ER level by the re-read operation.

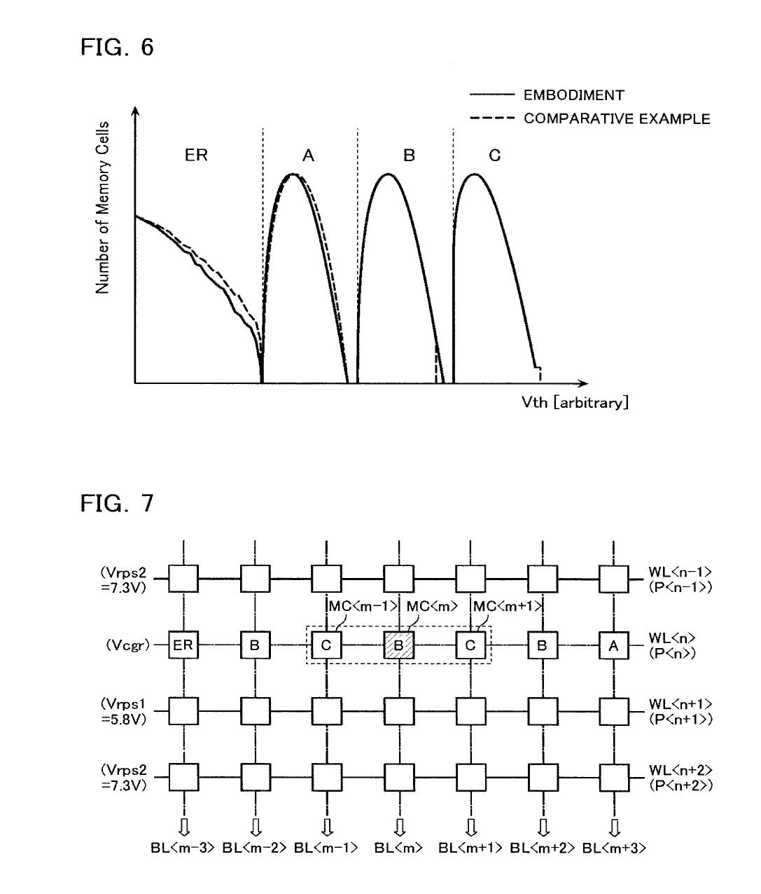

FIG. 6 illustrates the threshold voltage distributions read out by the re-read operation according to the present embodiment compared with the traditional read operation without re-reading.

FIG. 6 shows that the upper tail of the ER level and the A level is reduced by introducing the re-read operation, which gives broader threshold voltage margin between the ER and A levels and between the A and B levels. The term “margin” expresses gaps between two distributions. Such extension of threshold voltage margin contributes to improvement of reliability of the NAND flash memory.

A modified operations of the present embodiment are also considered.

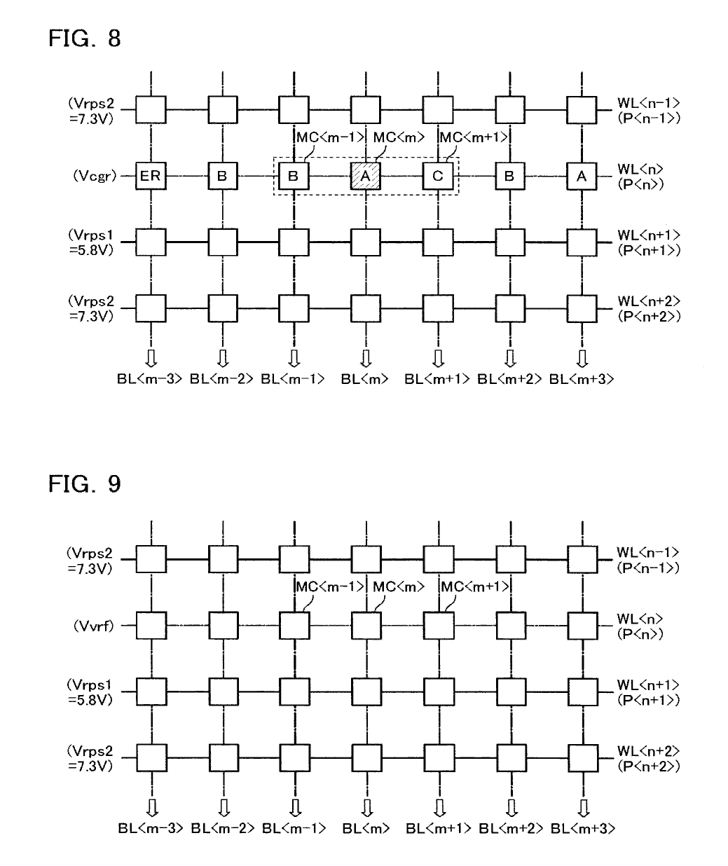

FIGS. 7 and 8 illustrate another read sequence in the nonvolatile semiconductor memory device according to the present embodiment.

The above-mentioned effects are applicable for all the cases where the incremental step-up programming to the adjacent cell MC goes on for some program loops after completion of programming to the selected cell MC. This condition is satisfied for most cell groups when the program level of at least either adjacent cell MC is higher than the selected cell MC.

FIG. 7 shows an example in which re-reading is executed on the selected cell MC (e.g., the shaded memory cell MC<m> in FIG. 7) of cell groups (e.g., a cell group surrounded by a dashed line in FIG. 7) with a pattern of the C level-B level-C level. FIG. 8 shows an example in which re-reading is executed on the selected cell MC (e.g., the memory cell MC<m> in FIG. 8) of cell groups (e.g., a cell group surrounded by a dashed line in FIG. 8) with a pattern of an arbitrary level-ER or A level-C level, that is, in a case where the selected cell MC is at the A level and one of adjacent cells MC of the selected cell MC is at the C level.

In both examples, programming to the selected cell MC<m> finishes earlier than at least one of the adjacent cells MC<m−1> and MC<m+1>, because the program level of at least one of the adjacent cells is higher than the selected cell MC<m>. Therefore, the incremental step-up programming to at least one of the adjacent cell goes on for several program loops after program completion of the selected cell MC<m>, and the selected cell MC<m> suffers inter-bit-line cell-to-cell interference from the adjacent cell MC<m−1> or MC<m+1>, which makes it possible to cancel the influence of the inter-bit-line cell-to-cell interference posteriorly by executing the re-read operation on the selected cell MC<m> and reading the threshold voltage Vth of the selected cell MC<m> seemingly low.

The present embodiment provides a way of poteriorly cancelling program errors by seemingly lowering threshold voltages of memory cells greatly influenced by the inter-bit-line cell-to-cell interference is great, as described heretofore. The margin between threshold voltage distributions can also be made large. As a result, it is possible to provide more reliable nonvolatile semiconductor memory devices.

### Second Embodiment

The second embodiment is the read sequence according to the first embodiment applied to a read sequence known as DLA (Direct-Lookahead).

Before describing the second embodiment of the present invention, the conventional DLA has to be described as a premise for the second embodiment to be more comprehensive.

FIGS. 9 to 12 illustrate the read sequence of the conventional DLA.

FIG. 9 illustrates the voltage configuration during the verify-read operation of a program sequence on the selected word line WL<n>, in which a verify voltage Vvrf is applied to the selected word line WL<n>, a verify-pass voltage Vvps1 (e.g. 5.8 V in FIG. 9) is applied to the adjacent word line WL<n+1>, and a verify-pass voltage Vvps2 (e.g. 7.3 V in FIG. 9) is applied to other unselected word lines WL. The verify-read operation by DLA often applies a lower verify-pass voltage to the adjacent word line WL<n+1> on the bit line BL side than other unselected word lines WL as shown in FIG. 9, and the program sequence is proceeded.

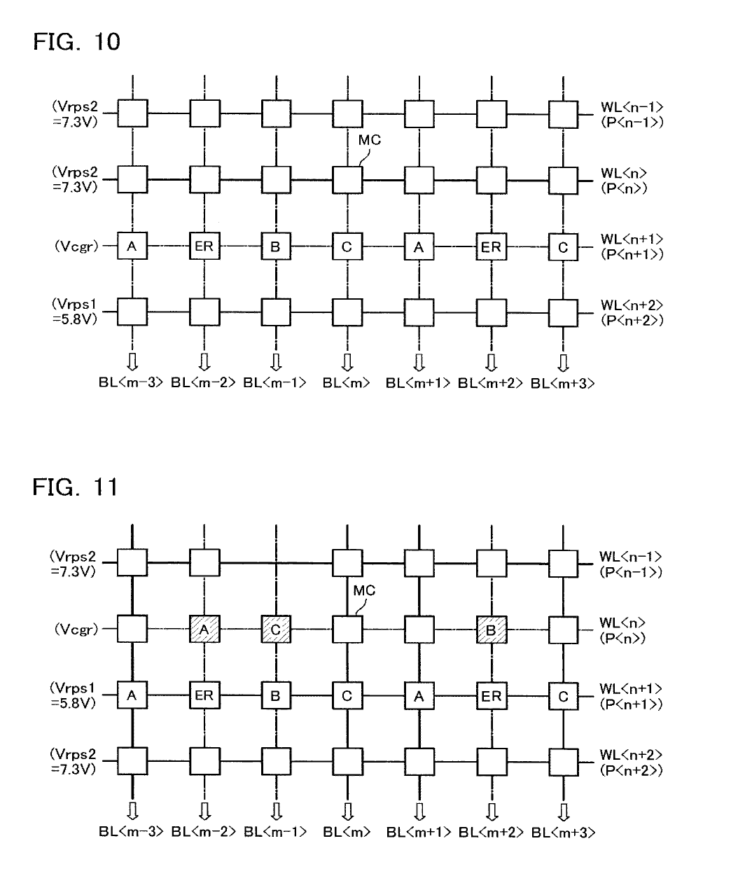

A read sequence on the selected page P<n> consists of three steps, that is, a pre-read operation, a first read operation, and a second read operation. The pre-read operation on the adjacent page P<n+1> is executed first. FIG. 10 illustrates the voltage configuration during the pre-read operation, in which the reference voltage Vcgr is applied to the adjacent word line WL<n+1>, the read-pass voltage Vrps1=5.8 V is applied to an unselected word line WL<n+2> adjacent to the adjacent word line WL<n+1>, and the read-pass voltage Vrps2=7.3 V is applied to the selected word line WL<n> and other word lines WL. FIG. 10 also shows the Vth level of each memory cell MC in the adjacent page P<n+1> found by this pre-read operation.

Subsequently, in FIG. 11, the first read operation on the selected page P<n> is executed. However, the first read operation is directed only for memory cells MC on which influence of the inter-word-line cell-to-cell interference is slight. Specifically, targets are memory cells MC whose the bit-line side adjacent cell is in the ER level or B level (e.g., shaded memory cells MC in FIG. 11). The threshold voltages Vth's of the Er and B levels do not shift greatly during U page program step. Here, the reference voltage Vcgr is applied to the selected word line WL<n>, the read-pass voltage Vrps1=5.8 V is applied to the adjacent word line WL<n+1>, and the read-pass voltage Vrps2=7.3 V is applied to other unselected word lines WL. FIG. 11 also shows the Vth level of each memory cell MC on the selected page P<n> found by the first read operation.

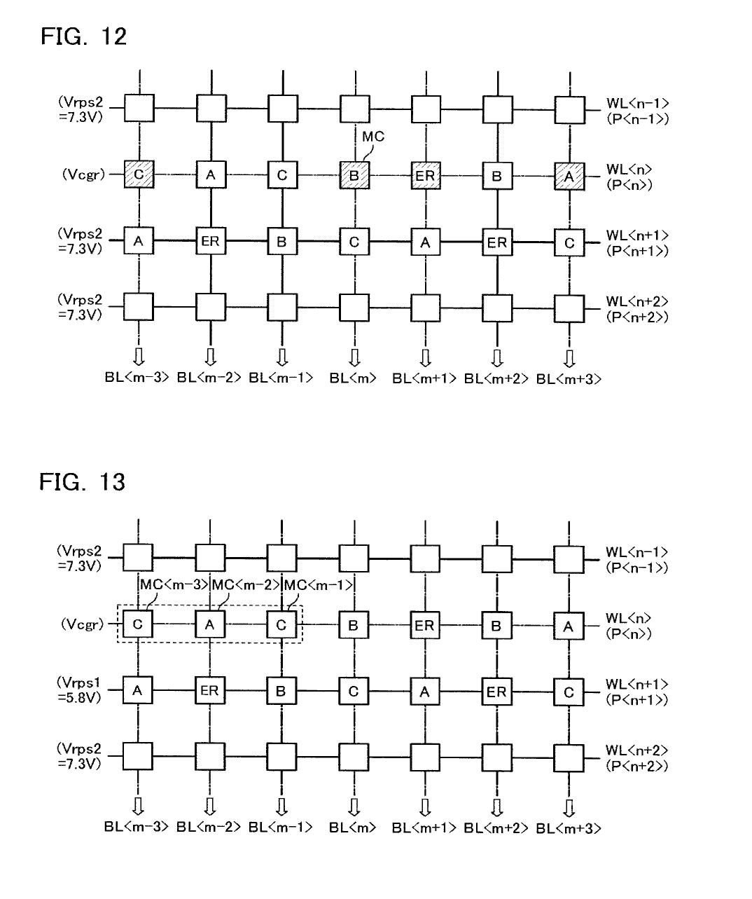

Finally, as shown in FIG. 12, the second read operation on the selected page P<n> is executed. However, the second read operation is directed for memory cells MC on which influence of the inter-word-line cell-to-cell interference is great and which are not targets in the first read operation (e.g., shaded memory cells MC in FIG. 12). Specifically, targets are memory cells MC whose the bit-line side adjacent cell is in the A level or C level. The A and C-level cells greatly change their threshold voltages during U page program step. In the second read operation, a read-pass voltage Vrps2 (e.g. 7.3 V in FIG. 12) higher than the first read operation is applied to the adjacent word line WL<n+1>. Other conditions are the same as those in the first read operation shown in FIG. 11. The second read operation lowers the threshold voltages Vth's of the memory cell MC that have suffered the great influence of the inter-bit-line cell-to-cell interference, because the read-pass voltage on the adjacent word line WL<n+1> is set higher than the verify-read operation and the first read operation. FIG. 12 also shows the Vth level in each memory cell MC on the selected page P<n> determined by the first and the second read operations.

According to the read sequence of the DLA system, different read operations are executed based on whether the influence of the inter-word-line cell-to-cell interference is large or small as described heretofore. As a result, it is possible to posteriorly cancel the influence of the inter-word-line cell interference on the threshold voltages Vth's of the memory cells MC.

On the basis of the read sequence of the DLA system described above, a read sequence in the present embodiment is now described as follows.

The read sequence of the present embodiment also consists of three steps, that is, a pre-read operation, a read operation, and a re-read operation.

First, the pre-read operation on the adjacent page P<n+1> shown in FIG. 10 is executed in the same way as the conventional DLA.

Subsequently, the read operation on the selected page P<n> is executed. FIG. 13 illustrates the voltage configuration of the read operation of the present embodiment. This read operation is conducted in a bias state similar to that in the first read operation in the conventional DLA. Here, however, targets are all memory cells MC in the selected page P<n>. FIG. 13 also shows the Vth level in each memory cell MC in the selected page P<n> determined by this read operation.

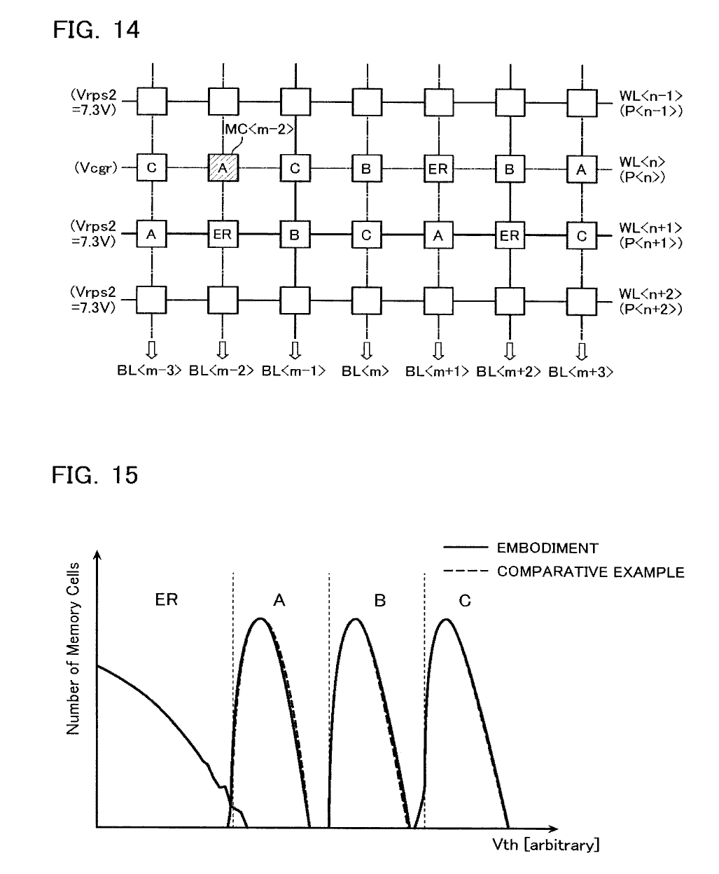

Finally, the re-read operation on the selected page P<n> is executed. FIG. 14 illustrates the voltage configuration of the re-read operation. This re-read operation is conducted in a bias state similar to that in the second read operation in the conventional DLA. Here, however, targets are memory cells MC in which the influence of inter-bit-line cell-to-cell interference is great, besides memory cells MC in which the influence of inter-word-line cell-to-cell interference is great. Specifically, besides the memory cells MC that have become targets in the second read operation in the conventional DLA, the selected cell MC (e.g., a shaded memory cell MC<m−2> in FIG. 14) is targeted to be re-read, if it is located at the center of a cell group (e.g., a cell group surrounded by a dashed line in FIG. 13) that coincides with a pattern of C level-ER or A level-C level. Final Vth levels of these target memory cells MC are determined by this re-read operation. This re-read operation lowers threshold voltages Vth's of memory cells MC influenced by inter-word-line cell-to-cell interference as well as inter-bit-line cell-to-cell interference greatly.

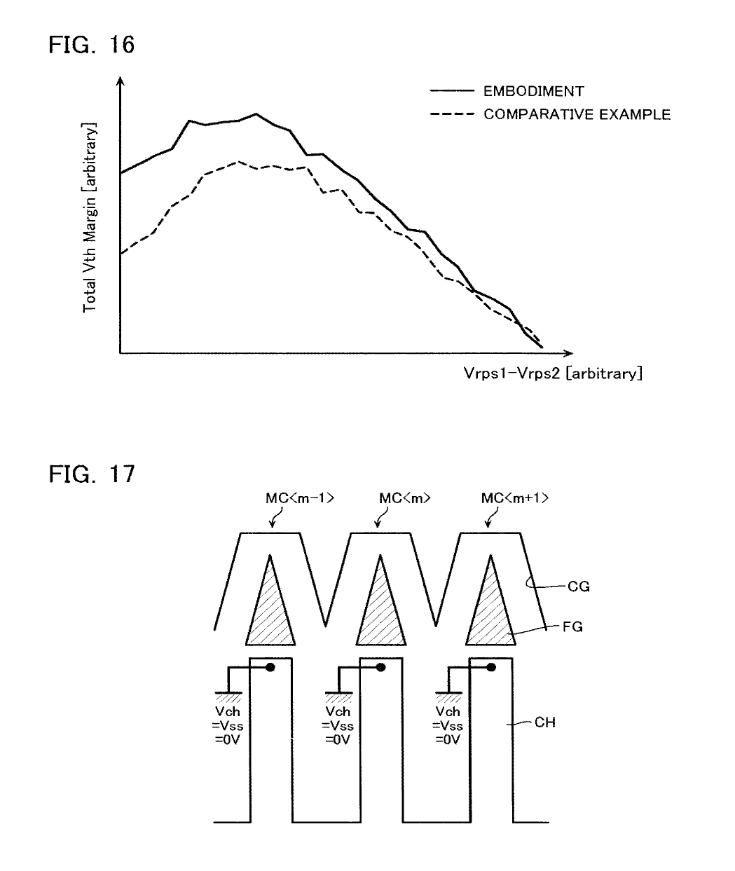

The read sequence in the present embodiment has the following effects: FIG. 15 shows the seeming threshold distributions of the present embodiment and the conventional DLA (comparative example). It can be seen from FIG. 15 that the upper tail of the ER level and the A level is reduced, and consequently a margin between the ER level and the A level and a margin between the A level and the B level are increased by adopting the present embodiment.

FIG. 16 shows the dependency of the threshold voltage margin on the difference (Vrps1−Vrps2) of the read-pass voltage of the read operation (Vrps1) and the re-read operation (Vrps2). Two curves in FIG. 16 correspond to the present embodiment and the conventional DLA.

It can be seen from FIG. 16 that the threshold voltage margin of the present embodiment is larger than the comparative example regardless of the read-pass voltage difference (Vrps1−Vrps2). This is because the read sequence in the present embodiment cancels not only the influence of inter-word-line cell-to-cell interference, but also the influence of inter-bit-line cell-to-cell interference by the re-read operation. On the other hand, the conventional DLA system cancels inter-word-like cell-to-cell interference only. In addition, the read sequence according to the present embodiment can be implemented without increase of number of read operation times compared to the comparative example. Therefore, time to read data does not increase. Note that the difference between the read-pass voltages (Vrps1−Vrps2) has an optimum value, and too large or too small (Vrps1−Vrps2) value results in reduction of the margin of the threshold voltage distributions.

The present embodiment described heretofore obtains the effect of reduction of influence of inter-word-line cell-to-cell interference in the read sequence of the conventional DLA without loss of the effect of the first embodiment. As a result, it is possible to provide a nonvolatile semiconductor memory device with further high reliability than the first embodiment.

### Third Embodiment

The foregoing embodiments are the nonvolatile semiconductor memory device that reads data by posteriorly cancels influence of inter-bit-line cell-to-cell interference caused during the program sequence. On the other hand, the third embodiment is a nonvolatile semiconductor memory device that suppresses influence of the channel-to-floating-gate interference during program sequence.

As described above, the program sequence in the nonvolatile semiconductor memory device is executed by repeating a program loop including the program operation and the verify-read operation.

The channel-to-floating-gate interference, which is caused between a channel and floating gate of a memory cell MC, occurs when programming of two adjacent memory cells MC in the same page complete by one program loop, that is, a memory cell finishes programming one program loop after or before its adjacent cell does.

In the following paragraphs, a program loop for the selected cell MC<m> and adjacent cells MC<m−1> and MC<m+1> is considered as an example to understand the channel-to-floating-gate interference of the program sequence in the nonvolatile semiconductor memory device.

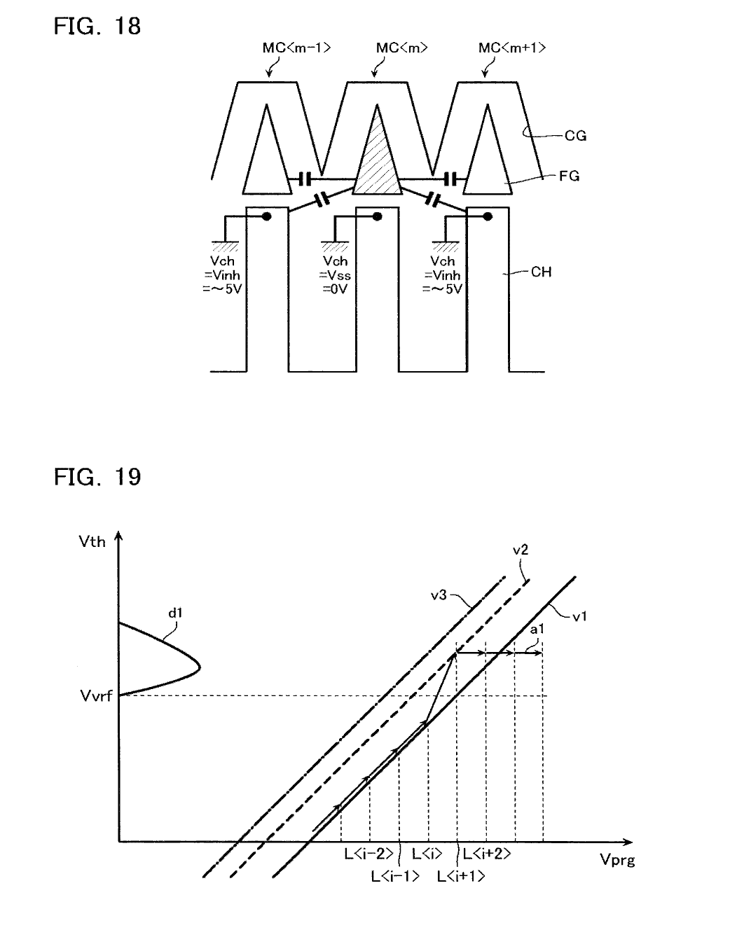

FIGS. 17 and 18 are schematic sectional views of memory cells MC<m−1> to <m+1> belonging to the same page. In FIGS. 17 and 18, CH denotes a channel of a memory cell, FG denotes a floating gate of the memory, and CG denotes a control gate of the memory.

FIG. 17 illustrates a case where the memory cells MC<m−1>, MC<m>, and MC<m+1> are program-permitted, and FIG. 18 is a case where the memory cell MC<m> is program-permitted and its adjacent cells MC<m−1> and MC<m+1> are program-inhibited. As shown in FIG. 18, a parasitic capacitance exists between the floating gate FG of the memory cell MC<m> and the channel CH of the adjacent memory cells MC<m−1> and MC<m+1>. If the adjacent cells are program-permitted as shown in FIG. 17, the channels of the adjacent cells are grounded (Vch=Vss). On the other hand, if the adjacent cells are program-inhibited as shown in FIG. 18, the channels of the adjacent cells are boosted up to Vch=Vinh (=˜5 V). Therefore, even if the program voltages of the control gate CG and the electric charge in the floating gate FG are equal between the both cases, the floating gate potential of the memory cell MC<m> of the case of FIG. 18 is higher than the case of FIG. 17 because of the parasitic capacitance from the adjacent cells, which causes difference in programming speed (i.e. the threshold voltages Vth of the memory cell MC of both cases are different after programming at the same program voltage Vprg on the control gate CG).

FIG. 19 shows a relation of a threshold voltage Vth of a memory cell to a program voltage Vprg during a program sequence. Denotations “L<i−2>” through “L<i+2>” in FIG. 19 indicate program loops at the corresponding program voltages.

In FIG. 19, v1 indicates program characteristics of the selected cell in a case where both adjacent cells are program-permitted, which corresponds to the case of FIG. 17, v2 indicates program characteristics of the case where only one adjacent cell is program-inhibited, and v3 indicates program characteristics of the case where both adjacent cells are program-inhibited, which corresponds to the case of FIG. 18. Because of the parasitic capacitance from the adjacent cells, v3 in FIG. 19 is the highest, v2 is the second high, and v1 is the lowest. Here a following case can be considered: All of the memory cells MC<m−1>, MC<m>, and MC<m+1> do not pass the program verification at a program loop L<i−1>. Therefore, all of the three memory cells are to be programmed at the next program loop L<i>. After the program operation of the program loop L<i>, only adjacent cells MC<m−1> and MC<m+1> pass the program verification while MC<m> does not. Therefore, only MC<m> is to be programmed at the next program loop L<i+1>. After the program operation of the program loop L<i+1>, MC<m> finally passes program verification. In such a case, the memory cell MC<m> follows a program characteristics curve al in FIG. 19. As can be seen from FIG. 19, the threshold voltage largely jumps from the program loop L<i> to L<i+1>, because the programming speed of the memory cell MC<m> at the program loop L<i+1> is higher than the program loop L<i> due to the parasitic capacitance from the adjacent cells.

If the threshold voltage of MC<m> has already reached slightly below the verify level at the program loop L<i>, the threshold voltage much exceeds the verify level at the program loop L<i+1> (over-programming), which results in broadening of the upper tail of the threshold voltage distribution.

This unfavorable phenomenon is called the channel-to-floating-gate interference.

The present embodiment provides a new program sequence to reduce influence of above-described problem.

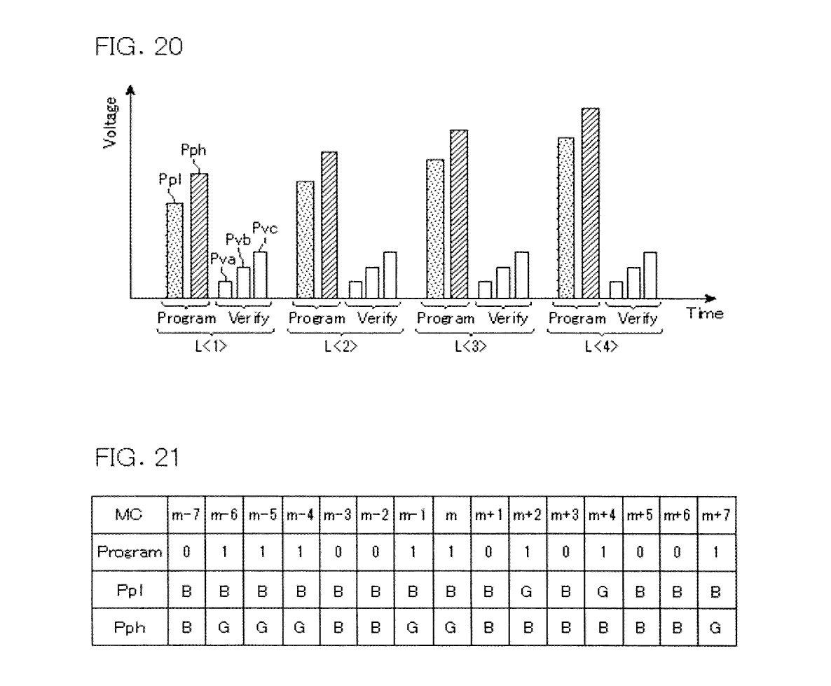

In the program sequence in the present embodiment, more than one program pulses are generated with different voltages every program operation as shown in FIG. 20. One program pulse among them is chosen for each selected cell to be programmed. The choice of the program pulse is based on whether program permission/inhibition pattern of the continuously placed memory cells coincides with a specific pattern.

FIG. 20 shows time evolution of program pulses and verify pulses during program sequence in the nonvolatile semiconductor memory device according to the present embodiment.

In the program sequence shown in FIG. 20, a program operation and a verify-read operation are executed every program loop L. In the program operation, a program pulse Ppl and a program pulse Pph are applied. The voltage of Pph is higher than Ppl. These program pulses Ppl and Pph are incrementally stepped up as the program loop L advances. On the other hand, in the verify-read operation, three verify pulses Pva, Pvb, and Pvc are applied for the verify voltage Vvrf=Va′, Vb′, and Vc′, respectively.

FIG. 21 shows which pulse is chosen for programming of each cell under an example of program data. In a “program” row in FIG. 21, “1” indicates that the regarding cell is program-permitted, whereas “0” indicates that the regarding cell is program-inhibited. Furthermore, “G” and “B” in “Ppl” and “Pph” rows indicate the channel state of a memory cell MC during the program pulse. “G” indicates grounded state (Vch=Vss), and “B” indicates a self-boosted (i.e. inhibited) state (Vch=Vinh). In other words, a program pulse marked as “G” among Pph and Ppl is chosen to program each memory cell MC.

In the program operation, either one of the program pulses Ppl and Pph is chosen for programming of the memory cell MC, and the channel of the memory cell is grounded during the chosen program pulse only. This choice is conducted based on whether continuous three programming data on a regarding cell and its both adjacent cells coincide with a pattern of inhibition-permission-inhibition (, which is defined as a “second reference pattern” hereafter). The channel-to-floating-gate interference on the regarding cell is the greatest for this case. If the programming pattern for the continuously placed three memory cells coincides with the second reference pattern, the lower program pulse Ppl is applied on the regarding cell (i.e. the center of the continuous three memory cells). If the programming pattern does not coincide with the second reference pattern, the higher program pulse Pph is applied on the regarding cell. In the example case shown in FIG. 21, continuously placed three memory cells MC<m+1>−MC<m+3> coincide with the program pattern of inhibition-permission-inhibition. Therefore, the center cell MC<m+2> is programmed with the lower program pulse Ppl. For another example, the program pattern for three continuous cells MC<m−1>−MC<m+1> is permission-permission-inhibited, which does not coincide with the second reference pattern. Therefore, the center memory cell MC<m> is programmed with a higher program pulse Pph. Furthermore, even in a case where the memory cells MC<m−1>−MC<m+1> are in permission-permission-inhibition pattern at the program loop L<i−1>, and the memory cell MC<m−1> passes the verification at the program loop L<i−1>, and the memory cells MC<m−1>−MC<m+1> shift to inhibition-permission-inhibition pattern at the program loop L<i>, the memory cell MC<m> does not suffer over-programming due to channel-to-floating-gate interference, because the programming pulse on the memory cell MC<m> is changed from the higher one (Pph) to the lower one (Ppl). Thus, over-programming of the memory cells can be suppressed by intentionally lowering the program pulse applied to program-permitted cells even in the case where the channel-to-floating-gate interference is great.

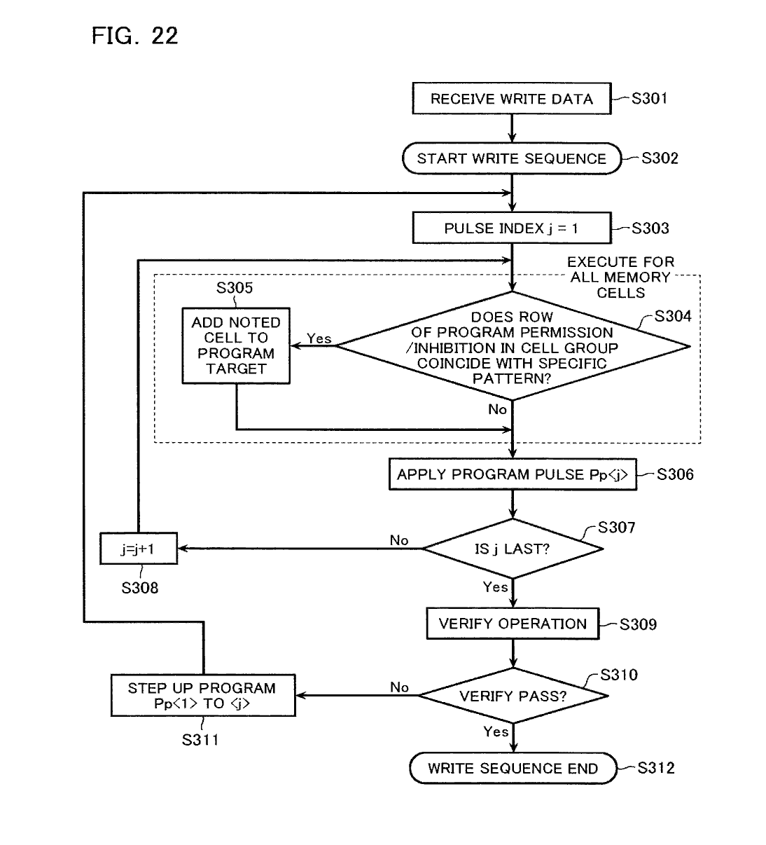

FIG. 22 shows a flow chart of the program sequence of the nonvolatile semiconductor memory device according to the present embodiment.

First, the page buffer 3 receives program data for the page P<n> at step S301. Then program sequence of the page P<n> is started at step 302.

Subsequently, the index j for the program pulse Pp<j> is initialized at step S303. Note that Pp<1>=Ppl and Pp<2>=Pph in the case of the example shown in FIGS. 20 and 21.

Subsequently, at step S304, each set of continuously placed three memory cells is judged whether its programming pattern coincides with inhibition-permission-inhibition pattern. This judgment is performed for all sets of continuously placed three memory cells whose center is the memory cell MC<1>−MC<M−1> (i.e. MC<0>−MC<1>−MC<2>, MC<1>−MC<2>−MC<3>, and so on). If the regarding memory cell MC, which is the center of each set of continuously placed three memory cells, is judged as a target of programming by the program pulse Pp<j>, the regarding cell is added to a list of memory cells to be programmed at step S305. On the other hand, in a case where the memory cell MC is not judged as a target of programming by the program pulse Pp<j>, the programming operation proceeds to the step S306.

Subsequently, at step S306, the program pulse Pp<j> is applied to memory cells in the selected page P<n>. During the program pulse Pp<j>, channels CH is biased to Vch=Vss for memory cells MC targeted to be programmed at the step S305. On the other hand, the channels CH of memory cells MC targeted not to be programmed at the step S305 are self-boosted (Vch=Vinh).

Subsequently, at step S307, the index j is examined if it indicates the last program pulse Pp<j>. In a case where Pp<j> is not the last program pulse, the program sequence proceeds to step S308. In a case where Pp<j> is the last program pulse, the program sequence proceeds to step S309. The index j of the program pulse Pp is incremented at the step S308, and the program sequence goes back to the step S304.

Subsequently, a verify-read operation on the selected page P<n> is executed at step S309.

Subsequently, at step S310, the number of cells that have not passed the verify-read operation S309 is counted and determined if it is less than a predetermined number. In a case where the number of cells that do not pass the verify-read operation is less than the predetermined number, the program sequence proceeds to step S311, otherwise the program sequence proceeds to step S312.

Subsequently, at step 311, the voltage (Vpgm) of the program pulse Pp is stepped up. Then, the program sequence returns to the step S303.

Finally, at step S312, the program sequence for the page P<n> is finished. Subsequently, a program sequence similar to the steps S301 to S312 is executed on a page P<n+1>

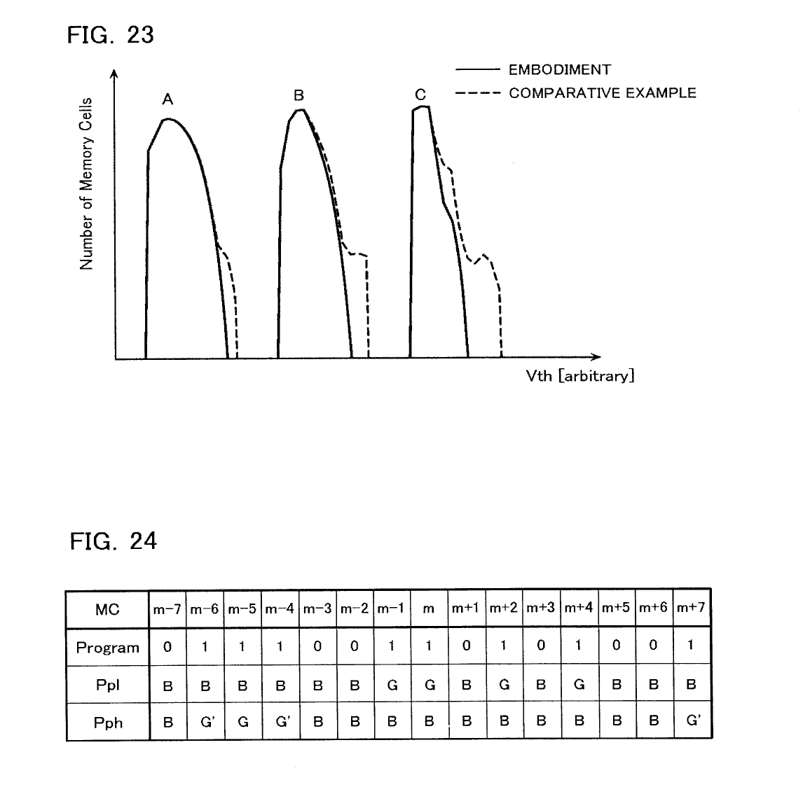

Effects of the program sequence in the present embodiment are as follows: FIG. 23 shows threshold voltage (Vth) distribution after the present program sequence. A comparative example in which the program operation is executed by using a single program pulse is also shown in FIG. 23. Note that the ER level is not shown in FIG. 23, since the ER level is not a target of the program.

It can be seen from FIG. 23 that the upper tail of the threshold voltage distribution is reduced for all of A, B, and C levels by adopting the present embodiment. We can also see from FIG. 23 that the threshold voltage margin between the A and B levels is increased as well as the margin between B and C.

The present embodiment is summarized as follows: Magnitude of the channel-to-floating-gate interference is judged based on the program permission/inhibition pattern of continuously placed three memory cells, and the program pulse to be applied on the center of the three memory cells is chosen based on the magnitude of influence, as described heretofore. As a result, the channel-to-floating-gate interference can be reduced during the program sequence. According to the present embodiment, therefore, it is possible to provide a highly reliable nonvolatile semiconductor memory device.

### Fourth Embodiment

In the third embodiment, the determination condition is that the program permission/inhibition pattern in a cell group coincides with the pattern of inhibition-permission-inhibition. This is because the pattern of inhibition-permission-inhibition is a pattern in which channel-to-floating-gate interference exerts the greatest influence on the selected cell. Besides this pattern, however, in a case where either one of cells adjacent to the selected cell is program inhibition, the channel-to-floating-gate interference exerts influence on the selected cell to some degree. In the fourth embodiment, therefore, a program sequence in which the determination condition is that at least one adjacent cell of the selected cell is program inhibition will be described.

Note that a voltage applied to the control gate during the program sequence in the present embodiment is the same as in the case of the third embodiment shown in FIG. 20. Therefore description thereof will be omitted.

A selection method of a program pulse in the program sequence in the present embodiment will now be described.

FIG. 24 is a diagram showing channel voltages of memory cells during the program sequence in the nonvolatile semiconductor memory device according to the present embodiment. In a program column shown in FIG. 24, “1” indicates a case where the program is permitted whereas “0” indicates a case where the program is inhibited. Furthermore, “G,” “G′” and “B” in a Ppl column and a Pph column indicate the channel voltage Vch of a memory cell MC in the program pulse. “G” indicates the ground voltage Vss, “B” indicates an inhibit voltage Vinh, and “G′” indicates a bias voltage Vbias which is slightly higher than the ground voltage Vss. Here, “G” and “G′” mean that programming is conducted on the memory cell MC by using the displayed program pulse.

In the program operation, either one of the program pulses Ppl and Pph is selected for the memory cell MC and the selected program pulse is applied to the memory cell MC. As for the selection of the program pulses Ppl and Pph, selection is conducted based on whether the program permission/inhibition pattern in a cell group A coincides with a pattern of permission/inhibition-permission-inhibition (third reference pattern), where the cell group A is a set of the selected cell and two adjacent cells. In a case where the program pattern coincides with this pattern, it is considered that the selected cell receives influence of the channel-to-floating-gate interference from at least one adjacent cell. Basically, in a case where the program permission/inhibition pattern in the cell group A coincides with the pattern of permission/inhibition-permission-inhibition, programming is conducted on the selected cell by using the low program pulse Ppl. Even in this case, however, in a case where the program is permitted for all memory cells MC in a cell group B, where the cell B is a set of at least three consecutive memory cells MC including the selected cell, programming is conducted by using the high program pulse Pph as exceptional processing. Even in this case, however, the program speed of the selected cell needs to be lowered, and consequently a bias voltage Vbias which is slightly higher than the ground voltage Vss (0 V) is applied to the channel voltage Vch of the selected cell.

Here, a case where the exceptional processing is not present will be considered. For example, in FIG. 24, memory cells MC<m−7> to <m−5> are set to be cell group A and memory cells MC<m−6> to <m−4> are set to be cell group B. It is supposed that the program loop L<i> has a row of program permission/inhibition pettern as shown in FIG. 24. In this case, a program operation is executed on the memory cell MC<m−5> by using the high program pulse Pph. At that time, however, the program permission/inhibition pattern in the cell group A is inhibition-permission-permission. Therefore, the center memory cell MC<m−6> originally needs to be programmed with the low program pulse Ppl. Nevertheless, the memory cell MC<m−6> is programmed by the high program pulse Pph as a part of the cell group B. If the memory cell MC<m−7> passes the verify in the preceding program loop L<i−1>, consequently a shift to the state of program permission/inhibition pattern as shown in FIG. 24 is conducted in the program loop L<i>, and the memory cell MC<m−6> has passed the verify in the program loop L<i> with a difference of one loop from the memory cell MC<m−7>, then in the program loop L<i> the memory cell MC<m−6> receives an assist effect from the memory cell MC<m−7> and in addition the memory cell MC<m−6> is written with the high program pulse Pph. As a result, the memory cell MC<m−6> receives the channel-to-floating-gate interference without being suppressed at all. As a result, the memory cell MC<m−6> receives great influence of the channel-to-floating-gate interference from the memory cell MC<m−7>. As a result, an over program on the memory cell MC<m−6> becomes apt to occur. In the present embodiment, the above-described exceptional processing is conducted to avoid such a situation.

On the other hand, in a case where the program permission/inhibition pattern in the cell group A does not coincide with the pattern of inhibition-permission-inhibition, the selected cell is programmed by using the high program pulse Pph.

A flow in the program sequence in the present embodiment will now be described.

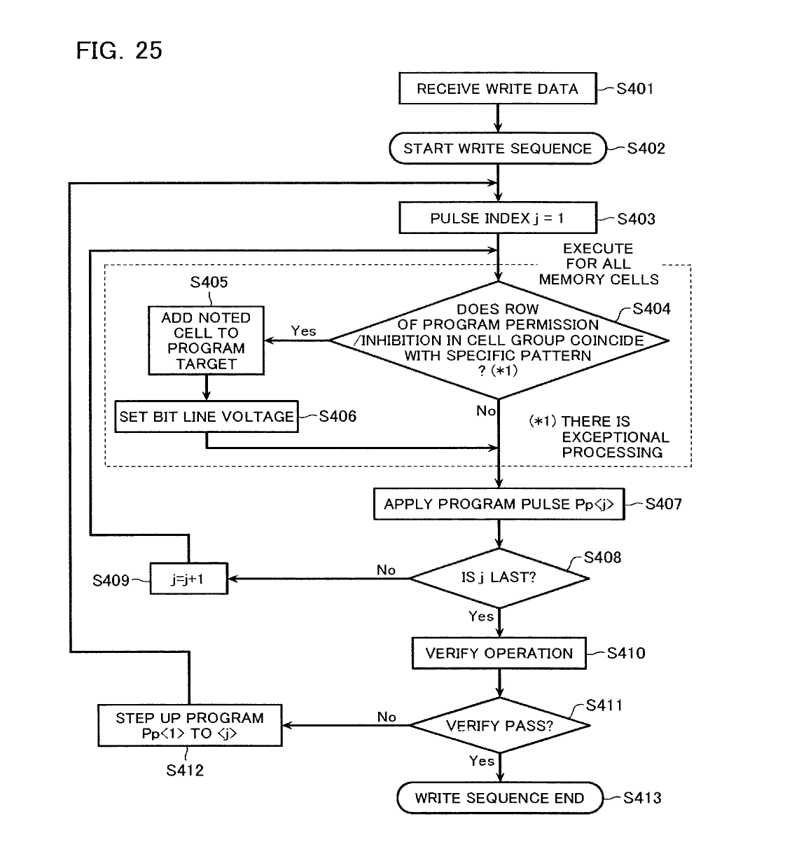

FIG. 25 is a flow chart of the program sequence in the nonvolatile semiconductor memory device according to the present embodiment.

First, at step S401, the page buffer 3 receives program data for the page P<n>. At step S402, a program sequence for the page P<n> is started.

Subsequently, at step S403, an index j in a program pulse Pp<j> is initialized. Note that in the case of the example shown in FIGS. 20 and 24, Pp<1>=Ppl and Pp<2>=Pph.

Subsequently, at step S404, it is determined with respect to each of cell groups A having the memory cells MC<0> to <M−1> as selected cells whether a row of program permission/inhibition pattern of the cell group A coincides with the pattern of permission/inhibition-permission-inhibition. In the present embodiment, at least three consecutive memory cells MC including the selected cell is regarded as cell group B, and exceptional processing described with reference to FIG. 24 is also considered. In a case where the selected cell MC is a target of a program using a program pulse Pp<j> as a result of the determination, this selected cell MC is added as a target of the program at step S405 and the processing proceeds to step S406. On the other hand, in a case where the selected cell MC is not a target of the program using the program pulse Pp<j>, the processing proceeds to step S407.

Subsequently, at step S406, a voltage on a bit line BL of the selected cell MC set to be a program target by the exceptional processing at step S404 is set. As a result, the channel of the selected cell MC is boosted up to Vch=Vbias.

Subsequently, at step S407, the program pulse Pp<j> is applied to memory cells MC in the page P<n>. At this time, at step S405, Vch=Vss is applied to a channel of a memory cell MC that has become a target of the program as a channel voltage, whereas Vch=Vinh is applied to a channel of a memory cell MC that has not become a target of the program as a channel voltage.

Subsequently, at step S408, it is determined whether the index j points to a final program Pp<j>. In a case where Pp<j> is not the final program pulse, the processing proceeds to step S409. In a case where Pp<j> is the final program pulse, the processing proceeds to step S410.

Subsequently, at step S409, the index j of the program pulse Pp is incremented. Then, the processing proceeds to step S404.

Subsequently, at step S410, a verify-read operation on the selected page P<n> is executed.

Subsequently, it is determined at step S411 whether all memory cells MC in the selected page P<n> have passed the verify-read operation at step S410. In a case where all memory cells MC have not passed the verify-read operation, the processing proceeds to step S412. In a case where all memory cells MC have passed the verify-read operation, the processing proceeds to step S413.

Subsequently, at step S412, height (Vpgm) of the program pulse Pp is stepped up. Then, the processing returns to step S403.

Finally, at step S413, the program sequence for the page P<n> is finished. Subsequently, a program sequence similar to steps S401 to S413 is executed on a page P<n+1>.

The program sequence in the present embodiment has been described heretofore.

Effects of the program sequence in the present embodiment will now be described.

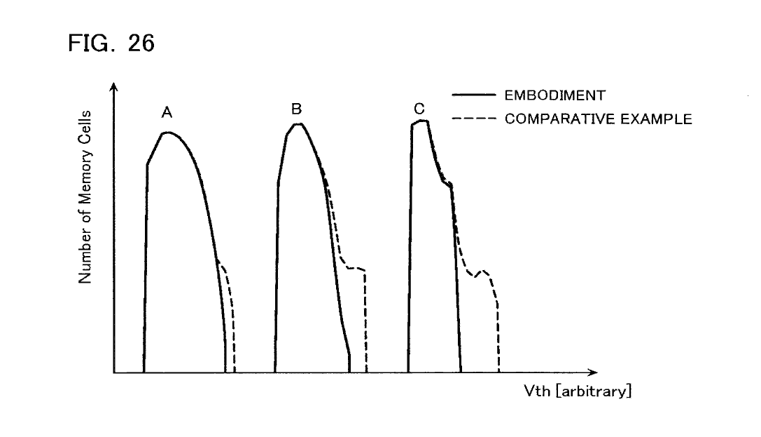

FIG. 26 is a diagram showing how threshold voltage distributes in a memory cell after the program sequence in the nonvolatile semiconductor memory device according to the present embodiment. A comparative example in which the program operation is executed by using a single program pulse is also shown in FIG. 26. Note that the ER level is not a target of the program, and consequently the ER level is not shown in FIG. 26.

It is appreciated from FIG. 26 that in the present embodiment the spread of the upper skirt of the threshold voltage distribution is reduced in all of the A level, the B level and the C level as compared with the comparative example. It is appreciated that consequently a margin between the A level and the B level and a margin between the B level and the C level have become large.

According to the present embodiment, therefore, it is possible to provide a nonvolatile semiconductor memory device that is high in data reliability in the same way as the third embodiment as described heretofore.

Note that the present embodiment can be applied to the first and second embodiments.

### Fifth Embodiment

In the fourth and fifth embodiments, greatness of influence of channel-to-floating-gate interference on a memory cell is judged based on the program permission/inhibition pattern of a cell group including the memory cell. And a program pulse is selected based on a result of the judgment. In the case of these embodiments, however, more than one program pulses are applied without fail in each program operation. Therefore, processing time becomes longer as compared with a program sequence in which the program operation is advanced with a single program pulse. In the present embodiment, therefore, a program sequence in which processing time of the program sequence is shortened without hampering effects of the fourth and fifth embodiments will be described.

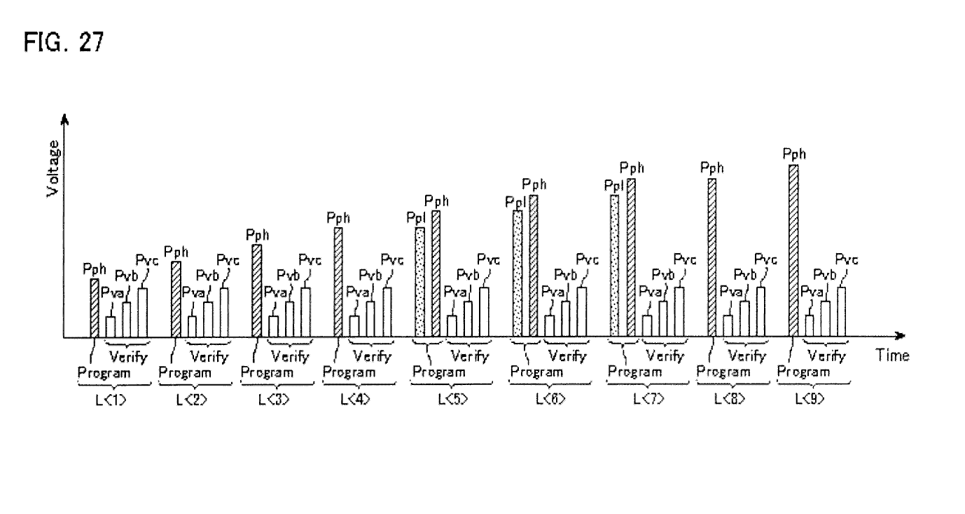

FIG. 27 is a diagram showing states of a program pulse and a verify pulse during a program sequence in the nonvolatile semiconductor memory device according to the fifth embodiment.

In the present embodiment as well, more than one program pulses that differ in height every program operation are prepared in the same way as the fourth and fifth embodiments. As for a predetermined number of first program loops and a predetermined number of last program loops in the program sequence, however, programming is conducted on all memory cells MC needing the program by using a single program pulse Pph regardless of the program permission/inhibition pattern of the cell group. Specifically, nine program loops L<1> to L<9> are shown in FIG. 27. As for four first program loops L<1> to <4> and two last program loops L<8> and L<9>, however, program operation is executed by using only the program pulse Pph.

As for the predetermined number of first program loops, the possibility that the program of the memory cell MC will be completed is low. Therefore, the possibility that the program of the selected cell MC will be completed in a program loop subsequent to a program loop in which a program of an adjacent cell MC is completed is extremely low. On the other hand, as for the predetermined number of last program loops, programs of a large number of memory cells MC have already been completed. Therefore, the possibility that the program of the selected cell MC will be completed in a program loop subsequent to that in which the program for the adjacent cell MC has completed is also extremely low. Even if the program is advanced with a single program pulse in the same way as the comparative example as for the predetermined number of first program loops and the predetermined number of last program loops, therefore, nearly the same effects as those in the third and fourth embodiments can be obtained.

A flow in the program sequence in the present embodiment will now be described.

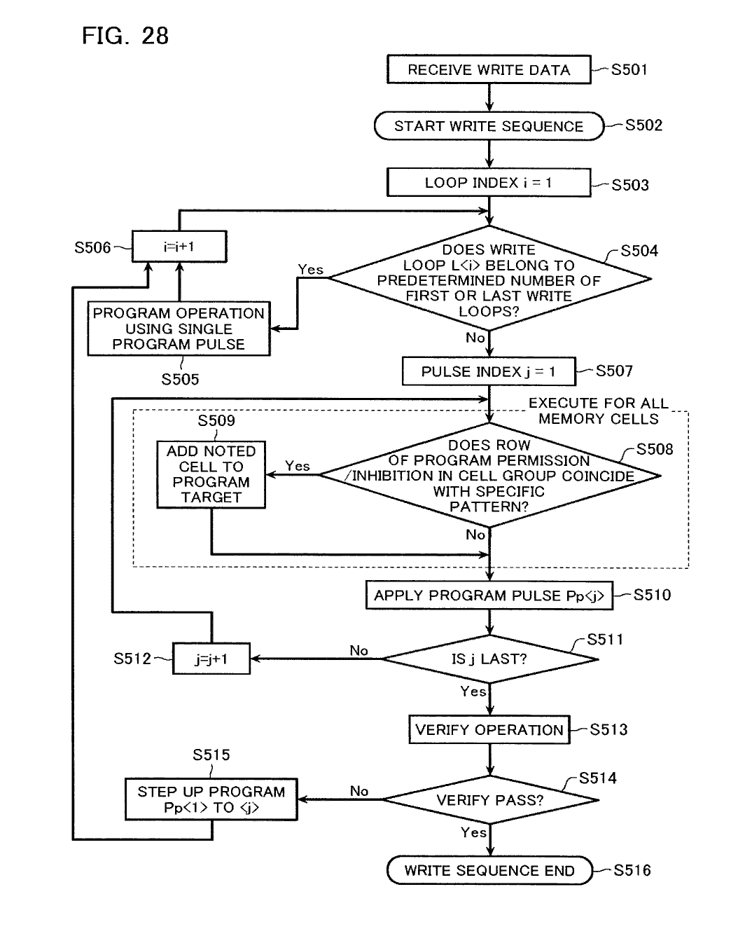

FIG. 28 is a flow chart of the program sequence in the nonvolatile semiconductor memory device according to the present embodiment.

First, at step S501, the page buffer 3 receives program data for the page P<n>. At step S502, a program sequence for the page P<n> is started.

Subsequently, at step S503, an index i in a program pulse L<i> is initialized.

Subsequently, at step S504, it is determined whether the program loop L<i> belongs to a predetermined number of first program loops in the program sequence or belongs to a predetermined number of last program loops in the program sequence. In a case where the program loop L<i> belongs to a predetermined number of first program loops or a predetermined number of last program loops in the program sequence as a result of the determination, the processing proceeds to step S505. Otherwise, the processing proceeds to step S507.

Subsequently, at step S505, a program operation is executed by using a single program pulse Pp in the same way as the comparative example. Then, the processing proceeds to step S506.

Subsequently, at step S506, an index i in the program loop L<i> is incremented. Then, the processing returns to step S504.

Subsequently, at step S507, an index j in the program pulse Pp<j> is initialized. Note that in the case of the example shown in FIG. 27, Pp<1>=Ppl and Pp<2>=Pph.

Subsequently, at step S508, it is determined with respect to each of cell groups having the memory cells MC<0> to <M−1> as selected cells whether a row of program permission/inhibition pattern of the cell group coincides with the pattern of inhibition-permission-inhibition. In a case where the selected cell MC is a target of a program using a program pulse Pp<j> as a result of the determination, this selected cell MC is added as a target of the program at step S509. On the other hand, in a case where the selected cell MC is not a target of the program using the program pulse Pp<j>, the processing proceeds to step S510.

Subsequently, at step S510, the program pulse Pp<j> is applied to memory cells MC in the selected page P<n> and a program operation is executed.

Subsequently, at step S511, it is determined whether the index j points to a final program Pp<j>. In a case where Pp<j> is not the final program pulse, the processing proceeds to step S512. In a case where Pp<j> is the final program pulse, the processing proceeds to step S513.

Subsequently, at step S512, the index j of the program pulse Pp is incremented. Then, the processing proceeds to step S508.

Subsequently, at step S513, a verify-read operation on the page P<n> is executed.

Subsequently, it is determined at step S514 whether all memory cells MC in the page P<n> have passed the verify-read operation at step S513. In a case where all memory cells MC have not passed the verify-read operation, the processing proceeds to step S515. In a case where all memory cells MC have passed the verify-read operation, the processing proceeds to step S516.

Subsequently, at step S515, height (Vpgm) of the program pulse Pp is stepped up. Then, the processing returns to step S506.

Finally, at step S516, the program sequence for the page P<n> is finished. Subsequently, a program sequence similar to steps S501 to S516 is executed on a page P<n+1>.

The program sequence in the present embodiment has been described heretofore.

Effects of the program sequence in the present embodiment will now be described.

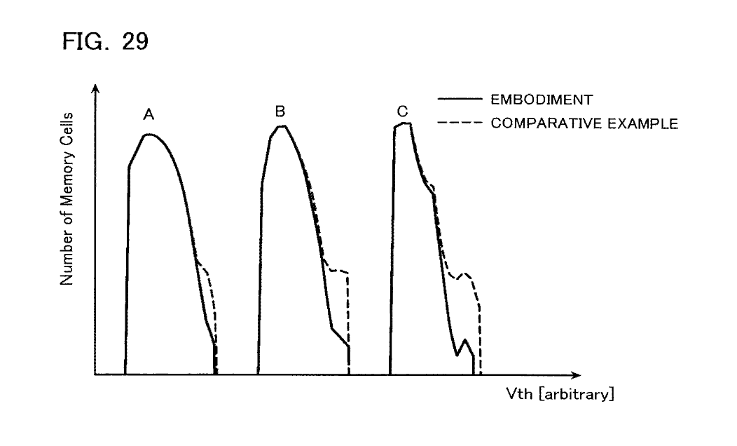

FIG. 29 is a diagram showing how threshold voltage distributes in a memory cell in the program sequence in the nonvolatile semiconductor memory device according to the present embodiment. A comparative example in which the program operation is executed by using a single program pulse is also shown in FIG. 29. Note that the ER level is not a target of the program, and consequently the ER level is not shown in FIG. 29.

It is appreciated from FIG. 29 that in the present embodiment the spread of the upper skirt of the threshold voltage distribution of the memory cell MC slightly spreads as compared with the third and fourth embodiments, but is reduced as compared with the comparative example.

According to the present embodiment, it is possible to implement a program sequence in which influence of channel-to-floating-gate interference is reduced while suppressing the increase of processing time as described heretofore. According to the present embodiment, therefore, it is possible to provide a nonvolatile semiconductor memory device that is high in data reliability.

Note that the present embodiment can be applied to the first to fourth embodiments.

### Sixth Embodiment

In the third to fifth embodiments, a nonvolatile semiconductor memory device executing a program sequence in which more than one program pulses are prepared and a program pulse is selected based on the program permission/inhibition pattern of a cell group has been described. In a sixth embodiment, a nonvolatile semiconductor memory device executing a program sequence in which a further larger number of program pulses are prepared and a program pulse is selected considering not only the program permission/inhibition pattern of the cell group but also program data of a memory cell will be described.

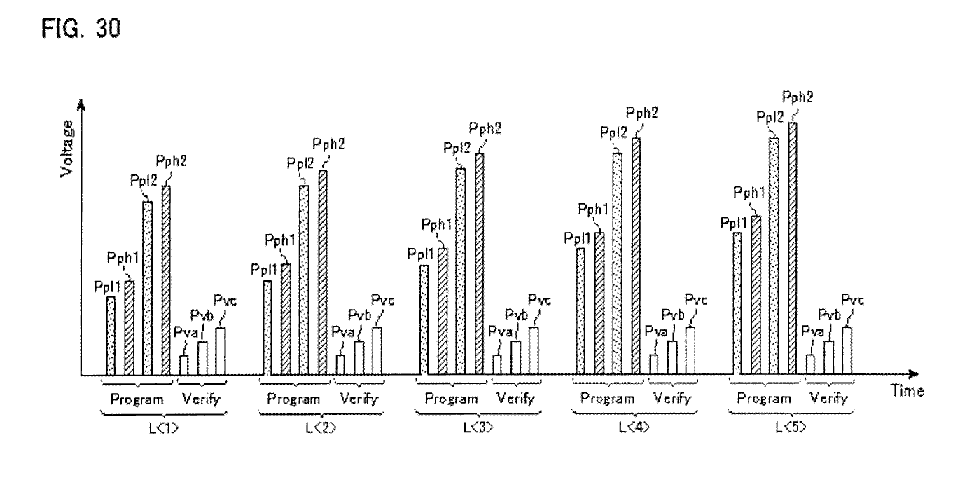

FIG. 30 is a diagram showing states of program pulses and verify pulses during a program sequence in the nonvolatile semiconductor memory device according to the sixth embodiment.

In the program sequence in the present embodiment, more than one program pulses selected based on the program permission/inhibition pattern of a cell group are prepared in the same way as the third to fifth embodiments. Furthermore, in the present embodiment, however, more than one sets each including the program pulses are prepared based on threshold voltages preset for the selected cell.

In the case of FIG. 30, four program pulses Ppl1, Ppl2, Pph1 and Pph2 which subsequently become higher in height every program operation are prepared. Among them, the program pulses Ppl1 and Ppl2 are used when setting the A level or B level for the memory cell MC. On the other hand, the program pulses Ppl2 and Pph2 are used when setting the C level for the memory cell MC. Furthermore, the program pulses Ppl1 and Ppl2 are used for the selected cell MC in a case where the program permission/inhibition pattern of the cell group coincides with the pattern of inhibition-permission-inhibition. The program pulses Pph1 and Pph2 are used for the selected cell MC in a case where the program permission/inhibition pattern of the cell group does not coincide with the pattern. By doing so, it is possible to increase the program speed of a memory cell MC to which the C level having the largest movement quantity of the threshold voltage Vth is set, during program operation. As a result, the number of times of execution of program loop can be made small. Furthermore, since the program permission/inhibition pattern of the cell group is considered in the same way as the third to fifth embodiments, it is also possible to suppress over-program on the selected cell.

Note that the difference between the program pulses Ppl1 and Ppl2 or the difference between the program pulses Pph1 and Pph2 becomes greater than the difference between the program pulses Ppl1 and Pph1 for setting the A level/B level or the difference between the program pulses Ppl2 and Pph2 for setting the C level. Therefore, program pulses for respective levels are prepared independently.

According to the present embodiment, it is possible to implement a program sequence that completes the program with fewer program loops as compared with the program sequence in the third to fifth embodiments, as described heretofore. As a result, it is possible to provide a nonvolatile semiconductor memory device that is short in processing time of the program sequence while obtaining effects similar to those in the third embodiment by adjusting the heights of program pulses and combining with the fifth embodiment.

Note that the present embodiment can be applied to the first to fifth embodiments.

### [Rest]

Heretofore, several embodiments of the present invention have been described. However, these embodiments have been presented as examples, and it is not intended to restrict the scope of the invention. These new embodiments can be executed in various other forms. Without departing from the spirit of the invention, various omissions, replacements and changes can be made. These embodiments and their modifications are included in the scope or spirit of the invention, and included in the invention stated in claims and an equivalent scope thereof.

What is claimed is:

1. A nonvolatile semiconductor memory device comprising:
a memory cell array configured to include more than one word lines and more than one memory strings, the memory strings having more than one memory cells connected in series, the memory cells being connected to the word lines; and
a control unit configured to execute a read sequence to read data page-by-page including more than one memory cells connected to one word line,
the control unit, during the read sequence on a first page,
executing a read operation by applying a first read-pass voltage to a second word line and reading data in the first page, and
executing a re-read operation by applying a second read-pass voltage different from the first read-pass voltage to the second word line and reading data in a first cell in a case where data read from a first cell group in the first page coincides with a specific first reference pattern,
where a first word line refers to one of the word lines that the control unit tries to read, the second word line refers to one of the word lines adjacent to the first word line, the page refers to data stored in memory cells connected to a whole word line, the first page refers to the page stored in the first word line, the cell group refers to one or more memory cells continuously placed and connected to the same word line, and the first cell refers to a memory cell belonging to the cell group and under judgment for being re-read.

2. The nonvolatile semiconductor memory device according to claim 1, wherein
the control unit re-reads data of the memory cell in the first page if specific first reference data are stored in a memory cell of a second page and the same memory string during re-read operation in the read sequence on the first page,
where the second page refers to the page including more than one memory cells connected to the second word line.

3. The nonvolatile semiconductor memory device according to claim 2, wherein
the control unit executes pre-read operation on the second page before read operation on the first page.

4. The nonvolatile semiconductor memory device according to claim 1, wherein
the second read-pass voltage is higher than the first read-pass voltage.

5. The nonvolatile semiconductor memory device according to claim 1, wherein
the memory cells have more than one different states distinguished by their threshold voltages corresponding to stored data,
the control unit executes a page-by-page program sequence by shifting the threshold voltages of memory cells,
a first state and a second state are included among the more than one different states of memory cells, magnitude of the threshold voltage shift of the second state is greater than the first state during the program sequence, and
the first reference pattern is a data pattern such that the first cell is in the first state and second cell is in the second state,
where the term “program” refers to writing data into memory cells, and the second cell refers to memory cell adjacent to the first cell and connected to the same word line as the first cell.

6. The nonvolatile semiconductor memory device according to claim 2, wherein
the memory cells have more than one different states distinguished by their threshold voltages corresponding to stored data,
the control unit executes a page-by-page program sequence by shifting the threshold voltages of memory cells,
a third state and a fourth state are included among the more than one different states of memory cells,
magnitude of the threshold voltage shift of the fourth state is greater than the third state during the program sequence, and
the memory state of the first reference data is the fourth state,
where the term “program” refers to writing data into memory cells.

7. The nonvolatile semiconductor memory device according to claim 1, wherein
the control unit applies the second read-pass voltage to the more than one memory cells except the first cell group during the read operation and re-read operation on the first page.

8. A nonvolatile semiconductor memory device comprising:
a memory cell array configured to include more than one word lines and more than one memory strings, the memory strings having more than one memory cells connected in series, the memory cells connected to the word lines; and
a control unit configured to execute a program sequence to program data page-by-page including more than one memory cells connected to one word line,
the control unit repeatedly executing program loops in which more than one program pulses with different voltages are generated and the threshold voltages of memory cells are shifted by applying one of the program pulses during the program sequence,
the control unit choosing the program pulse to be applied on a first cell based on whether the permission/inhibition pattern of a second cell group coincides with a specific second reference pattern during certain one of the program loops of the program sequence on the first page,
the second reference pattern is a permission/inhibition pattern such that the first cell is permitted and the second cells are inhibited,
where the first cell refers to the memory cell under judgment for choice of the program pulse, the second cells refers to the memory cells belonging to the same page as the first cell and adjacent to the first cell, and the second cell group refers to a set of the first cell and the second cells.

9. The nonvolatile semiconductor memory device according to claim 8, wherein
a first program pulse and a second program pulse are included among the program pulses,
the voltage of the second program pulse is higher than the first program pulse,
the control unit applies the first program pulse on the first cell in a case where the program permission/inhibition pattern of the second cell group coincides with the second reference pattern, and
the control unit applies the second program pulse on the first cell in a case where the program permission/inhibition pattern of the second cell group does not coincide with the second reference pattern and the first cell is program permitted.

10. The nonvolatile semiconductor memory device according to claim 8, wherein
the control unit applies the same program pulse to the first cells in the second cell group regardless of the program permission/inhibition pattern for predetermined number of first program loops in the program sequence.

11. The nonvolatile semiconductor memory device according to claim 8, wherein
the control unit applies the same program pulse to the first cells in the second cell group regardless of the program permission/inhibition pattern for predetermined number of last program loops in the program sequence.

12. The nonvolatile semiconductor memory device according to claim 9, wherein
the memory cells have more than one states including fifth and sixth states distinguished by their threshold voltages corresponding to stored data,
magnitude of the threshold voltage shift of the sixth state is greater than the fifth state during the program sequence, and
the program pulses for the fifth-state cells and the sixth-state cells each include the first program pulse and the second program pulse, respectively.

13. The nonvolatile semiconductor memory device according to claim 12, wherein
the voltage difference between the first or second program pulses for programming the fifth state and the sixth state is larger than the voltage difference between the first program pulse and the second program pulse for programming the fifth state or the sixth state.

14. A nonvolatile semiconductor memory device comprising:
a memory cell array configured to include more than one word lines and more than one memory strings, the memory strings having more than one memory cells connected in series, the memory cells being connected to the word lines; and
a control unit configured to execute a program sequence to program data page-by-page including more than one memory cells connected to one word line,
the control unit repeatedly executing program loops in which more than one program pulses with different voltages are generated and the threshold voltages of memory cells are shifted by applying one of the program pulses during the program sequence,
the control unit choosing the program pulse to be applied on the first cell based on whether the permission/inhibition pattern of the third cell group coincides with a specific third reference pattern during certain one of the program loops of the program sequence on the first page,
the third reference pattern is a permission/inhibition pattern such that the first cell is permitted and second cells are inhibited,
where the first cell refers to the memory cell under judgment for choice of the program pulse, the second cells refer to the memory cells belonging to the same page as the first cell and adjacent to the first cell, and the third cell group refers to a set of the first cell and the second cells.

15. The nonvolatile semiconductor memory device according to claim 14, wherein
the more than one program pulses include a third program pulse and a fourth program pulse higher than the third program pulse,
the control unit, during the certain program loops of the program sequence on the first page,
applies the third program pulse to the first cell in a case where the program permission/inhibition pattern coincides with the third reference pattern and the first cell is not included in the fourth cell group,
applies the fourth program pulse to the first cell in a case where the program permission/inhibition pattern coincides with the third reference pattern and the first cell is included in the fourth cell group, and
applies the fourth program pulse to the first cell in a case where the program permission/inhibition pattern does not coincide with the third reference pattern,
where the fourth cell group refers to a set of at least three continuously placed memory cells connected to the same word line, and the all the memory cells in the fourth cell group are program-permitted.

16. The nonvolatile semiconductor memory device according to claim 15, wherein
the memory cells include channels, charge storage layers formed on the channels, control gates formed on the charge storage layers and connected to the word lines,
the control unit, during the program sequence on the first page,
applies one of the program pulses to the word line connected to the first cell,
applies a first channel voltage to one of the channels of the first cell in a case where the first cell is program-inhibited,
applies a second channel voltage lower than the first channel voltage to the channel of the first cell in a case where the first cell is program-permitted, the program permission/inhibition pattern coincides with the third reference pattern, and the first cell is included in the fourth cell group, and
applies a third channel voltage lower than the second channel voltage to the channel of the first cell in other cases.

17. The nonvolatile semiconductor memory device according to claim 14, wherein
the control unit applies the same program pulse to the first cells in the third cell group regardless of the program permission/inhibition pattern for predetermined number of beginning program loops in the program sequence.

18. The nonvolatile semiconductor memory device according to claim 14, wherein
the control unit applies the same program pulse to the first cells in the third cell group regardless of the program permission/inhibition pattern for predetermined number of last program loops in the program sequence.

19. The nonvolatile semiconductor memory device according to claim 15, wherein
the memory cells have more than one states including seventh and eighth states distinguished by their threshold voltages corresponding to stored data,
magnitude of the threshold voltage shift of the eighth state is greater than the seventh state during the program sequence, and
the program pulses for the seventh-state cells and the eighth-state cells each include the third program pulse and the fourth program pulse, respectively.

20. The nonvolatile semiconductor memory device according to claim 19, wherein
the voltage difference between the third or fourth program pulses for programming the seventh state and the eighth state is larger than the voltage difference between the third program pulse and the fourth program pulse for programming the seventh state or the eighth state.
